(19) United States
(12) Patent Application Publication
(10) Pub. No.: US 2005/0229226 A1
(43) Pub. Date: Oct. 13, 2005

(54) Method employing power-saving modes in electronic devices decoding and displaying multimedia-programs

(75) Inventors: Sandeep Relan, Bangalore (IN); Brajabandhu Mishra, Bangalore (IN); Rajendra Khare, Bangalore (IN)

Correspondence Address: MCANDREWS HELD & MALLOY, LTD, 500 WEST MADISON STREET, SUITE 3400, CHICAGO, IL, 60661, US

(73) Assignee: Broadcom Corporation

(21) Appl. No.: 10/864,121

(22) Filed: Jun. 9, 2004

Related U.S. Application Data
(63) Continuation of application No. 10/819,868, filed on Apr. 7, 2004.
(63) Continuation-in-part of application No. 10/826,183, filed on Apr. 16, 2004.

(51) Int. Cl. H04N 7/025; H04N 7/16; H03L 7/00; H04N 7/173; H04N 7/10

(52) U.S. Cl. 725/114; 725/118; 725/100; 725/144

(57) ABSTRACT

Disclosed herein is a method and system for employing power-saving states/modes in electronic devices. The electronic device may be adapted to determine whether an end-user is physically present when the electronic device is in operation or when an end-user display apparatus is inactive. The electronic device may be adapted to prompt an end-user to respond with an appropriate response. Upon determining that the end-user is not physically present, the electronic device may be adapted to enter at least one of a plurality of power-saving modes. The end-user, the network, and the electronic device may each be able to set the power-saving modes. The electronic device may also enter at least one of a plurality of power-saving modes by default. The electronic device may be adapted to maintain an end-user's settings and preferences by employing the power-saving modes.

### RELATED APPLICATIONS

The present application is a Continuation of U.S. Non-Provisional patent application Ser. No. ______ having Attorney Docket Number 15794US01, filed on Jun. 9, 2004, entitled METHOD EMPLOYING PERSONAL MULTIMEDIA-PROGRAM RECORDING APPLICATIONS IN ELECTRONIC DEVICES, and hereby incorporates herein by reference the complete subject matter thereof in its entirety.

The present application is a Continuation-In-Part of U.S. Non-Provisional patent application Ser. No. ______ having Attorney Docket Number 15468US01, filed on Apr. 7, 2004, entitled UNICAST CABLE CONTENT DELIVERY, and hereby incorporates herein by reference the complete subject matter thereof in its entirety.

The present application is also a Continuation-In-Part of U.S. Non-Provisional patent application Ser. No. ______ having Attorney Docket Number 15485US01, filed on Apr. 16, 2004, entitled SYSTEM AND METHOD FOR MULTIMEDIA VIEWERSHIP SURVEYING, and hereby incorporates herein by reference the complete subject matter thereof in its entirety.

### FEDERALLY SPONSORED RESEARCH OR DEVELOPMENT

[Not Applicable]

### MICROFICHE/COPYRIGHT REFERENCE

[Not Applicable]

### BACKGROUND OF THE INVENTION

Cable television (TV) has become a widely subscribed to commodity. Cable TV typically comprises a plurality of audio/video (A/V) transmissions accumulated in a central office, for example. The A/V transmissions may be accumulated in a content server, for example.

A content server is an information storage unit adapted to collect, accumulate, package, disseminate, and broadcast multimedia-program data/information to clients at various locations remote from the central office.

A common central content server may be located in a central office of a service provider. The content server may comprise a plurality of servers residing in multiple geographic locations.

Typically, cable TV transmissions (channels) are distributed to end-users over cables, thus cable TV. The channels may be distributed from a content server located at a local cable TV service provider's location. The service provider's content server is adapted to transmit all of the channels simultaneously on a single shared cable to an end-user location.

Multiple clients, end-users, and/or customers subscribe to the channels and/or services provided by the content server of the service provider. A television set and a set-top-box (STB) may be located at the end-user's location to decode and display the channels. The STB provides end-users access to (i.e., decodes) only those channels that the end-user subscribes.

Ordinarily, there may be a signal distribution unit situated at the cable TV service provider's location. The signal distribution unit may be adapted to receive all channels via at least one satellite signal-receiving unit, and subsequently via at least one satellite. The subscribing end-user's STB is connected to the end-user's TV set. The end-user may be provided with a smart card for authentication and identification purposes.

Each end-user may subscribe to different channel packages and the number of channels subscribed to by each end-user may vary. Cables connect the signal distribution unit at the service provider's location to each STB and TV set at each individual end-user location. The signal distribution unit transmits all of the received channels to all of the end-user locations at once.

The STB is adapted to permit access to (viewing of) channels that the end-user has subscribed, while barring access to (denying viewing of) channels that the end-user has not subscribed. The end-user may select a subscribed channel for viewing by remotely controlling the STB, causing the STB to decode and send a particular channel to the TV set for display and viewing.

Occasionally, end-user's switch off their TV sets and leave the STB switched on. When an end-user is not viewing received and decoded multimedia-program content, i.e., when the STB is left switched on, power is being wasted.

Occasionally, end-users forget to switch off both their TV sets and the STB. When an end-user is not viewing received, decoded, and displayed multimedia-program content, i.e., when the TV set and the STB are left switched on, power is being wasted.

Further limitations and disadvantages of conventional and traditional approaches will become apparent to one of skill in the art, through comparison of such systems with some aspects of the present invention as set forth in the remainder of the present application with reference to the drawings appended hereto.

### SUMMARY OF THE INVENTION

Aspects of the present invention may be found in a multimedia-program distribution network. The network may comprise a plurality of electronic devices communicatively coupled to the network and a power control module. The power control module may be adapted to monitor power consumption of at least one of the plurality of electronic devices.

In an embodiment according to the present invention, the power control module may be adapted to determine whether an end-user is present and receiving a multimedia-program from an electronic device.

In an embodiment according to the present invention, if the power control module determines that an end-user is one of absent from the electronic device, unresponsive to the electronic device, and a display apparatus is inactive, the power control module may be adapted to reduce the power consumption of the electronic device by commanding the electronic device to enter at least one of a plurality of power-saving modes.

In an embodiment according to the present invention, determining whether the display apparatus is one of active and inactive may comprise evaluating at least one component of the display apparatus.

In an embodiment according to the present invention, the at least one of a plurality of power-saving modes may comprise at least one of a POWER-ON mode, a STAND-BY mode, a POWER-OFF mode, a HIBERNATE mode, an electronic device-determined mode, an end-user-determined mode, and a network-determined mode.

In an embodiment according to the present invention, determining whether an end-user is present and receiving the multimedia-program from the electronic device may comprise prompting the end-user to respond to a message delivered by the electronic device.

In an embodiment according to the present invention, the message delivered by the electronic device may comprise one of an audio message, a visual message, and a combination audio/video message.

In an embodiment according to the present invention, responding to the message delivered by the electronic device may comprise pressing one of a button and a key on at least one of a remote control device, the electronic device, and a peripheral associated electronic device.

In an embodiment according to the present invention, responding to the message delivered by the electronic device may comprise pressing a sequence of one of buttons and keys on at least one of the remote control device, the electronic device, and the peripheral associated electronic device.

In an embodiment according to the present invention, responding to the message delivered by the electronic device may comprise entering at least one of a password and username on at least one of the remote control device, the electronic device, and the peripheral associated electronic device.

In an embodiment according to the present invention, responding to the message delivered by the electronic device may comprise entering a particular response to an interactive question delivered by the electronic device upon at least one of the remote control device, the electronic device, and the peripheral associated electronic device.

In an embodiment according to the present invention, responding to the message delivered by the electronic device may comprise employing a biometric authentication technique via at least one of the remote control device, the electronic device, and the peripheral associated electronic device.

In an embodiment according to the present invention, the plurality of electronic devices and the network may be adapted to communicate via one of a wire, a cable, an optical fiber, and wirelessly in two-way communication.

In an embodiment according to the present invention, a multimedia-program may comprise one of audio, video, text, documents, Internet communication, and wireless telephony.

In an embodiment according to the present invention, the plurality of electronic devices may comprise an audio decoding entity, a video decoding entity, and a combination audio/video decoding entity.

In an embodiment according to the present invention, the plurality of electronic devices may comprise an audio broadcast entity, a video display entity, and a combination audio/video display entity.

In an embodiment according to the present invention, the plurality of electronic devices may comprise firmware and software adapted to employ a plurality of power-saving modes.

In an embodiment according to the present invention, the plurality of electronic devices may comprise one of a digital multimedia-program recorder, a video cassette player, a video cassette recorder, a digital video disc player, a digital video disc recorder, an MP3 audio player, a mobile cellular phone, a wired telephone, a wireless cellular handset, a personal digital assistant, an audio tape player, an audio tape recorder, a compact disc player, a compact disc recorder, a digital still camera, a digital video camera, and a gaming console.

In an embodiment according to the present invention, the network may further comprise at least one multimedia-program distribution device.

In an embodiment according to the present invention, the network may further comprise at least one satellite receiving and transmitting distributed multimedia-program information.

In an embodiment according to the present invention, the network may further comprise at least one satellite receiver receiving the transmitted distributed multimedia-program information and conveying the distributed multimedia-program information to at least one local service provider location for dissemination to the plurality of electronic devices.

In an embodiment according to the present invention, the network may further comprise a subscriber database memory. The subscriber database memory may be accessed to determine whether a particular end-user is subscribed to and authorized to receive a particular multimedia-program being requested.

Aspects of the present invention may be found in an electronic device comprising at least one decoder for decoding audio and video information, a transmitter for transmitting multimedia-program requests to a multimedia-program distribution network, a receiver for receiving multimedia-program information transmitted from the multimedia-program distribution network, and a power control module for monitoring and evaluating power consumption of the electronic device.

In an embodiment according to the present invention, the power control module may be adapted to implement and employ at least one of a plurality of power-saving modes to reduce power consumption and prevent power waste.

In an embodiment according to the present invention, the at least one of a plurality of power-saving modes comprises at least one of a POWER-ON mode, a STAND-BY mode, a POWER-OFF mode, a HIBERNATE mode, an electronic device determined mode, an end-user determined mode, and a network determined mode.

In an embodiment according to the present invention, the power control module may be adapted to determine whether an end-user is present and receiving a multimedia-program from the electronic device.

In an embodiment according to the present invention, the electronic device may be adapted to prompt the end-user to respond to a message delivered by the electronic device.

In an embodiment according to the present invention, the message delivered by the electronic device may comprise one of an audio message, a visual message, and a combination audio/video message.

In an embodiment according to the present invention, responding to the message delivered by the electronic device may comprise pressing one of a button and a key on at least one of a remote control device, the electronic device, and a peripheral associated electronic device.

In an embodiment according to the present invention, responding to the message delivered by the electronic device may comprise pressing a sequence of one of buttons and keys on at least one of the remote control device, the electronic device, and the peripheral associated electronic device.

In an embodiment according to the present invention, responding to the message delivered by the electronic device may comprise entering at least one of a password and username on at least one of the remote control device, the electronic device, and the peripheral associated electronic device.

In an embodiment according to the present invention, responding to the message delivered by the electronic device may comprise entering a particular response to an interactive question delivered by the electronic device upon at least one of the remote control device, the electronic device, and the peripheral associated electronic device.

In an embodiment according to the present invention, responding to the message delivered by the electronic device may comprise employing a biometric authentication technique via at least one of the remote control device, the electronic device, and the peripheral associated electronic device.

In an embodiment according to the present invention, the electronic device may be adapted to communicate via one of a wire, a cable, an optical fiber, and wirelessly in two-way communication with the multimedia-program distribution network.

In an embodiment according to the present invention, a multimedia-program may comprise one of audio, video, text, documents, Internet communication, and wireless telephony.

In an embodiment according to the present invention, the power control module may be adapted to determine whether a display apparatus is one of active and inactive.

In an embodiment according to the present invention, the at least one decoder for decoding audio and video information may comprise at least one of an audio decoding entity, a video decoding entity, and a combination audio/video decoding entity.

In an embodiment according to the present invention, the electronic device may further comprise at least one of an audio broadcast entity, a video display entity, and a combination audio/video display entity.

In an embodiment according to the present invention, the electronic device may comprise one of a digital multimedia-program recorder, a video cassette player, a video cassette recorder, a digital video disc player, a digital video disc recorder, an MP3 audio player, a mobile cellular phone, a wired telephone, a wireless cellular handset, a personal digital assistant, an audio tape player, an audio tape recorder, a compact disc player, a compact disc recorder, a digital still camera, a digital video camera, and a gaming console.

In an embodiment according to the present invention, the electronic device may be adapted to determine whether a particular end-user is subscribed to and authorized to receive a particular multimedia-program being requested before sending a multimedia program request to the multimedia-program distribution network, If the end-user is unsubscribed and unauthorized to receive the particular multimedia-program requested, the electronic device may deliver a message to the end-user.

In an embodiment according to the present invention, the transmitter and the receiver may comprise one of a single entity and separate entities.

In an embodiment according to the present invention, the power control module may be adapted to determine whether a display apparatus is one of active and inactive by evaluating at least one component of the display apparatus.

Aspects of the present invention may be found in a method of controlling power consumption in an electronic device. The method may comprise monitoring activity of the electronic device and entering at least one of a plurality of power-saving modes upon determining that the electronic device is wasting power.

In an embodiment according to the present invention, determining that the electronic device is wasting power may at least comprises one of determining that an end-user is absent from the electronic device and determining that an electronic device's service is unused by an end-user.

In an embodiment according to the present invention, determining that the electronic device is wasting power may also comprises determining whether a display apparatus is one of active and inactive.

In an embodiment according to the present invention, determining that the end-user is absent and the electronic device's service is unused may comprise prompting the end-user to respond to a message and waiting a particular amount of time to receive a response.

In an embodiment according to the present invention, the method may further comprise entering the at least one power saving mode if no response is received.

In an embodiment according to the present invention, the method may further comprise receiving the response, evaluating the response, and authenticating the response. If the response is determined to be authentic, the electronic device may determine that the end-user is present and using the electronic device's service.

In an embodiment according to the present invention, the response may comprise an input received from one of a button and a key pressed on at least one of a remote control device, the electronic device, and a peripheral associated electronic device.

In an embodiment according to the present invention, the response may comprise an input received from a sequence of one of buttons and keys pressed on at least one of the remote control device, the electronic device, and the peripheral associated electronic device.

In an embodiment according to the present invention, the response may comprise an input received from at least one of a password and username entered on at least one of the remote control device, the electronic device, and the peripheral associated electronic device.

In an embodiment according to the present invention, the response may comprise an input received from a particular response to an interactive question delivered by the electronic device entered on at least one of the remote control device, the electronic device, and the peripheral associated electronic device.

In an embodiment according to the present invention, the response may comprise an input received from a biometric authentication technique via at least one of the remote control device, the electronic device, and the peripheral associated electronic device.

In an embodiment according to the present invention, the method may further comprise receiving the response, evaluating the response, and authenticating the response. If the response is determined to be inauthentic, the electronic device may determine that a valid end-user is absent and may enter at least one of the plurality of power-saving modes and/or a security mode.

In an embodiment according to the present invention, the at least one of a plurality of power-saving modes comprises at least one of a POWER-ON mode, a STAND-BY mode, a POWER-OFF mode, a HIBERNATE mode, an electronic device determined mode, an end-user determined mode, and a network determined mode.

In an embodiment according to the present invention, in the POWER-OFF mode, all circuits of the electronic device are one of switched off and inactive.

In an embodiment according to the present invention, in the STAND-BY mode, a portion of the electronic device circuits are one of switched on and active and a portion of the electronic device circuits are one of switched off and inactive.

In an embodiment according to the present invention, in the HIBERNATE mode, the electronic device circuits associated with maintaining in a volatile memory one of an end-user's settings and an end-user's preferences may remain active and a balance of the electronic device circuits may be one of switched off and inactive.

In an embodiment according to the present invention, in the POWER-ON mode, all circuits of the electronic devices may be one of switched-on and active.

In an embodiment according to the present invention, monitoring activity of the electronic device may be performed during electronic device start-up. Upon determining that a valid end-user is present, the electronic device may be adapted to enter the POWER-ON mode.

In an embodiment according to the present invention, determining whether a display apparatus is one of active and inactive may comprise evaluating at least one component of the display apparatus.

In an embodiment according to the present invention, the electronic device may enter the POWER-ON mode upon being switched on, wherein monitoring activity of the electronic device may be performed. The electronic device may enter a different power-saving mode depending upon whether an end-user is one of present and absent.

In an embodiment according to the present invention, the electronic device may enter the POWER-ON mode upon being switched on, wherein monitoring activity of the electronic device may be performed. The electronic device may enter a different power-saving mode depending upon whether a display apparatus is one of active and inactive.

In an embodiment according to the present invention, the electronic device may enter a power saving mode when an end-user presses one of a button and a key on at least one of a remote control device, the electronic device, and a peripheral associated electronic device.

In an embodiment according to the present invention, the electronic device may enter a power saving mode when an end-user presses a sequence of one of buttons and keys on at least one of the remote control device, the electronic device, and the peripheral associated electronic device.

In an embodiment according to the present invention, the electronic device may enter a power saving mode when an end-user enters at least one of a password and username on at least one of the remote control device, the electronic device, and the peripheral associated electronic device.

In an embodiment according to the present invention, the electronic device may enter a power saving mode when an end-user enters a particular response to an interactive question delivered by the electronic device upon at least one of the remote control device, the electronic device, and the peripheral associated electronic device.

In an embodiment according to the present invention, the electronic device may enter a power saving mode when an end-user employs a biometric authentication technique via at least one of the remote control device, the electronic device, and the peripheral associated electronic device.

In an embodiment according to the present invention, the electronic device may enter a power-saving mode depending upon a state of at least a portion of at least one of hardware, firmware, and software in the electronic device.

These and other features and advantages of the present invention may be appreciated from a review of the following detailed description of the present invention, along with the accompanying figures in which like reference numerals refer to like parts throughout.

### BRIEF DESCRIPTION OF SEVERAL VIEWS OF THE DRAWINGS

FIG. 1 is a perspective diagram illustrating a satellite transmission/reception system in accordance with an embodiment of the present invention;

FIG. 2 is a perspective diagram illustrating a multimedia-program display device and a multimedia-program decoder/receiver/transmitter device in accordance with an embodiment of the present invention;

FIG. 3 is a perspective diagram illustrating a wireless/cable-ready portable mobile multimedia-program decoder/transmitter/receiver/display device in accordance with an embodiment of the present invention;

FIG. 3A is a block diagram illustrating a multimedia-program distribution network in accordance with an embodiment of the present invention;

FIG. 3B is a block diagram illustrating a multimedia-program distribution and power control and monitoring system in accordance with an embodiment of the present invention;

FIG. 4A is a block diagram illustrating a cable multimedia-program distribution network in accordance with an embodiment of the present invention;

FIG. 4B is a block diagram illustrating a wireless multimedia-program distribution network in accordance with an embodiment of the present invention;

FIG. 5 is a block diagram illustrating a set-top-box multimedia-program unit in accordance with an embodiment of the present invention;

FIG. 5A is a block diagram illustrating a multimedia-program processing unit incorporated within a mobile display device having power control features in accordance with an embodiment of the present invention;

FIG. 6 is a diagram illustrating a plurality of available power control states/modes applicable by the multimedia-program processing unit incorporated within a mobile display device having power control features according to an embodiment of the present invention;

FIG. 7 is a flow diagram illustrating a method of personal multimedia-program recording using an electronic device according to an embodiment of the present invention;

FIG. 8 is a flow diagram illustrating a method of personal multimedia-program recording and playback using an electronic device according to an embodiment of the present invention;

FIG. 9 is a flow diagram illustrating a power-saving and power control method facilitated by determining whether an end-user is viewing and physically in the presence of the electronic device in accordance with an embodiment of the present invention; and

FIG. 10 is a flow diagram illustrating a method suggesting and program power-saving states/modes in accordance with an embodiment of the present invention.

### DETAILED DESCRIPTION OF THE INVENTION

Aspects of the present invention may be found in providing power-saving states/modes and applying power-saving methods to electronic devices, for example, digital television (TV) products. A digital TV product may be defined as a display device having built-in digital multimedia-program decoding and multimedia-program display hardware, firmware, and/or software functionality, for example, a TV set having integrated STB functionality.

In an embodiment according to the present invention, power-saving states/modes and power-saving methods may be provided in and applied toward a plurality of additional consumer electronic devices, for example, digital program recorders, video cassette players, video cassette recorders, digital video disc players, digital video disc recorders, MP3 audio players, mobile cellular phones, wired telephones, wireless cellular handsets, personal digital assistants, audio tape players, audio tape recorders, compact disc players, compact disc recorders, digital still cameras, digital video cameras, computer gaming consoles, etc.

Aspects of the present invention may also be found in power-saving states/modes and power-saving methods being applied in conjunction with a plurality of personal multimedia-program recording applications. Personal multimedia-program recording applications may be defined as end-user initiated and/or end-user issued commands to consumer electronic devices, such as, for example, a STB, a digital TV product, or any of the personal consumer electronic devices set forth above, to record a requested channel, transmission, or multimedia-program being broadcast at a later time, for example. The electronic devices set forth above may also be adapted to prompt end-users to suggest commands and to select commands appropriate to particular end-users' viewing preferences.

For example, personal multimedia-program recording applications may comprise, for example, an electronic device prompting an end-user to record a first multimedia-program and a second multimedia-program (or a plurality of multimedia-programs thereof) by interacting with the electronic device prior to the time a program broadcast is to occur, thus removing the necessity of the end-user being physically present when a program begins to initiate a recording procedure.

Aspects of the present invention may be found in a plurality of power states/modes employable by the electronic devices to regulate power usage, reduce power consumption, increase battery life, and prolong the useful life of devices' electronic components. In an embodiment according to the present invention, the power states/modes applicable to consumer electronic devices may comprise at least the following: a POWER-ON state/mode; a POWER-OFF state/mode; a STAND-BY state/mode; and a HIBERNATE state/mode.

In an embodiment according to the present invention, the POWER-ON state/mode may be defined as the power state/mode wherein all of the electronic and electric circuits of an electronic device are switched on or are electrically/electronically active.

In an embodiment according to the present invention, the POWER-OFF state/mode may be defined as the power state/mode wherein all of the electronic and electric circuits of an electronic device are switched off or are electrically/electronically inactive.

In an embodiment according to the present invention, STAND-BY state/mode may be defined as the power state/mode wherein at least some, but not all, of the electronic and electric circuits of an electronic device are switched on and are electrically/electronically active. For example, in a STB or digital TV product, during the STAND-BY state/mode, the display-related electronic and electrical circuits may be are electrically/electronically inactive or switched off, whereas the decoding-related electronic and electrical circuits may be are electrically/electronically active or switched on.

In an embodiment according to the present invention, the HIBERNATE state/mode may be defined as the power state/mode wherein none, an insignificant number, and/or very few electronic and electric circuits of an electronic device are switched on and/or are electrically/electronically active. For example, in a STB or digital TV product, during the HIBERNATE state/mode, end-user settings/preferences may be saved in a non-volatile memory, wherein electronic and/or electrical circuits adapted to and/or related to retrieving the end-user settings/preferences during a transition from the HIBERNATE state/mode to the POWER-ON mode/state or STAND-BY mode/state, for example, may be electrically/electronically active.

In an embodiment according to the present invention, an end-user may choose to watch multiple recorded programs at a one or a plurality of later time(s) In an embodiment according to the present invention, the electronic device may prompt the end-user to issue/select playback command(s) to initiate playback of recorded multimedia-programs at a particular date(s) and time(s).

In an embodiment according to the present invention, the electronic device may HIBERNATE, (i.e., enter the HIBERNATE state/mode), after receiving and storing/saving a plurality of end-user commands, for example, record, playback, etc. The electronic device may remain in the HIBERNATE state/mode until entering the STAND-BY state/mode, for example. Upon entering the STAND-BY state/mode, the electronic device may initiate recording of a first selected multimedia-program. The electronic device may remain in the STAND-BY state/mode until completion of recording the first selected multimedia-program, wherein the electronic device may once again re-enter the HIBERNATE state/mode until another selected program-related event is imminent.

The above recited sequence of program-related and power-saving events may be repeated for additional multimedia-program recording and program-related events. At some later time, the electronic device may exit the HIBERNATE state/mode and enter the POWER-ON state/mode. Upon entering the POWER-ON state/mode, a display device/entity of the electronic device may be switched on and the electronic device may initiate playback of recorded multimedia-programs or perform another program-related event.

Aspects of the present invention may be found in a plurality of power-saving states/modes being automatically enabled/disabled and controlled by an electronic device. In an embodiment according to the present invention, the electronic device may prompt the end-user to provide/select a plurality of commands associated with a plurality of multimedia-programming-related events. The electronic device may be adapted to store and evaluate the commands, determine appropriate power-saving states/modes to efficiently perform the commands, enable/disable and initiate the determined appropriate power-saving states/modes, and carry out the end-user issued/selected program-related commands.

In an embodiment according to the present invention, responding to a message delivered by the electronic device may comprise pressing one of a button and a key on at least one of a remote control device, the electronic device, and a peripheral associated electronic device.

In an embodiment according to the present invention, responding to a message delivered by the electronic device may comprise pressing a sequence of one of buttons and keys on at least one of the remote control device, the electronic device, and the peripheral associated electronic device. The peripheral associated electronic device may comprise an STB, a digital TV product, etc., for example.

In an embodiment according to the present invention, responding to a message delivered by the electronic device may comprise entering at least one of a password and username on at least one of the remote control device, the electronic device, and the peripheral associated electronic device. The peripheral associated electronic device may comprise an STB, a digital TV product, etc., for example.

In an embodiment according to the present invention, responding to a message delivered by the electronic device may comprise entering a particular response to an interactive question delivered by the electronic device upon at least one of the remote control device, the electronic device, and the peripheral associated electronic device. The interactive question may comprise a code, text, a number, or some other pre-set or assignable information that an end-user may be able to easily remember. The peripheral associated electronic device may comprise an STB, a digital TV product, etc., for example.

In an embodiment according to the present invention, responding to a message delivered by the electronic device may comprise employing a biometric authentication technique via at least one of the remote control device, the electronic device, and the peripheral associated electronic device.

In an embodiment according to the present invention, a biometric authentication technique may comprise at least one of a fingerprint analysis, an iris or other eye scanning analysis, a facial recognition technique, a voice recognition technique, etc. for example. The peripheral associated electronic device may comprise at least one device adapted to carry out at least one of the above-mentioned biometric techniques. The peripheral associated electronic device may comprise an STB, a digital TV product, etc., for example.

Aspects of the present invention may be found in an automatic switch-on feature in an electronic device. In an embodiment according to the present invention, the electronic device may be provided with a real-time clock built into the electronic device. The real-time clock may also support and be associated with the power-saving states/modes active in the electronic device.

In an embodiment according to the present invention, the clock may be an automatic time/date-setting clock or may be a clock that may be manually set by an end-user. The automatic time/date-setting clock may be adapted to determine a current correct local time/date by evaluating time/date information contained in a received multimedia-program transmission or other received transmission.

In an embodiment according to the present invention, the automatically time/date-setting clock may comprise a long life re-chargeable battery adapted to retain correct time in and for the electronic device during long periods of inactivity and/or long periods of absence from an external electrical power source.

Aspects of the present invention may also be found in a method of determining whether an end-user is physically present when program is being displayed or when a program-related display event, selected/issued by the end-user, is initiated by the electronic device. In an embodiment according to the present invention, the end-user may be prompted to press a button(s) on a remote control device to indicate that the end-user is physically present and to confirm that a recorded multimedia-program is to be displayed or a program-related event is to be performed by the electronic device at the selected time/date.

In an embodiment according to the present invention, the end-user may be prompted to enter a password comprising a sequence of buttons/keys on a remote control device, for example. The end-user may also be prompted to enter an alphanumeric value(s) displayed on the display device/entity. The electronic device may randomly generate the alphanumeric value(s) displayed on the display device/entity, for example.

Aspects of the present invention may be found in ensuring that an end-user is actively watching displayed program by displaying an alphanumeric string on the display device/entity, wherein the end-user may be prompted to type the same alphanumeric string or a responsive password with a remote control device.

If the end-user is not physically present and/or an appropriate response to the prompt is not received, the electronic device may be adapted to enter one of the HIBERNATE state/mode, the STAND-BY state/mode, or the POWER-OFF state/mode, after a brief period of response time has elapsed.

In an embodiment according to the present invention, determining whether an end-user is or is not physically present may comprise the electronic device displaying a recorded visual message on the display device entity in conjunction with transmitting a recorded audio message. The combination audio/video determination method may be selected from an options menu during set-up of the electronic device. The audio/video determination method may comprise a recorded audio/video message.

For example, after displaying an end-user interactive prompt, as set forth above, and failing to receive a corresponding response, the following message may be simultaneously visually displayed and audibly transmitted. “The television set will enter the STAND-BY mode in 10 seconds. 10, 9, 8, 7, 6, 5, 4, 3, 2, 1, Good-Bye.”

In an embodiment according to the present invention, if an end-user fails to notice the visually displayed end-user interactive prompt, the end-user may hear the audible message and press an appropriate key(s)/button(s) preventing the electronic device form entering a power-saving state/mode.

In an embodiment according to the present invention, the end-user interactive prompt may also provide anti-theft protection and/or disabling a lost or stolen electronic device making the electronic device unserviceable to a finder or thief of the electronic device.

For example, the power-saving modes may be enhanced to prompt an end-user to enter a password comprising an alphanumeric string enterable on a remote control device, during entry into the POWER-ON state/mode. For example, if an incorrect value is typed multiple times, such as, three times, the electronic device may be adapted to display a visual alarm and/or transmit an audio alarm.

In another embodiment according to the present invention, if an incorrect value is typed multiple times, such as, three times, the electronic device may be adapted to enter the POWER-OFF state/mode. Alarm option settings may be applied or selected by entering an options menu during an initial set-up of the electronic device.

Aspects of the present invention may be found in a digital circuit board or application specific integrated circuit (ASIC) integrated into an electronic device for performing the power-saving methods and controlling power-saving states/modes and. In an embodiment according to the present invention, the power-saving states/modes and power-saving methods may be provided as firmware/software in an integrated circuit, a programmable logic device, or a chip. The integrated circuit, programmable logic device, or chip may be installed and may operate in a STB, a digital TV product, or any other electronic device, as set forth above.

Aspects of the present invention may be found in application of power-saving states/modes according to, for example, the Advanced Power Management (APM) standard, the Advanced Configuration and Power Interface (ACPI) standard, the Display Power Management System (DPMS) standard, etc. The DPMS standard, for example, is a power management system adapted to reduce energy consumption of computer monitors, when a computer is idle.

Aspects of the present invention may be found in power-saving states/modes implemented in stand-alone STBs. In an embodiment according to the present invention, the STBs may comprise mobile wireless enabled STBs. Power considerations for wireless mobile devices are important.

In an embodiment according to the present invention, a battery or a plurality of batteries may supply power for the electronic devices. The batteries may be standard dry-cell batteries, alkaline batteries, Lithium batteries, etc. The batteries may also be rechargeable-type batteries. The batteries may be rechargeable without removal from (i.e., within) the electronic devices or alternatively may be removable, replaceable, and/or rechargeable after being removed from the electronic devices.

In an embodiment according to the present invention, the electronic devices may be provided with a power control processor or logic controller adapted to regulate the power usage, reduce the power consumption, and increase the battery life by evaluating the power usage and ensuring that power is not being wasted when the electronic devices are idle or when an end-user is not present to receive the multimedia-program information being displayed.

In another embodiment according to the present invention, the electronic devices may be provided with a general-purpose processor adapted and/or configured to implement power-saving states/modes and power-saving methods as firmware/software stored in the electronic device.

In an embodiment according to the present invention, end-user settings and/or preferences may be stored in a non-volatile memory device, for example, a FLASH memory or an additional secondary storage device, such as, a hard drive, which does not consume power maintaining stored information.

Aspects of the present invention may be found in methods of setting the plurality of power-saving states/modes set forth above. In an embodiment according to the present invention, the electronic device may prompt an end-user to set the power-saving modes. The electronic device may be provided with an end-user viewable and accessible options menu having a plurality of power-saving options for the end-user to select. The electronic device may be adapted to suggest (prompt) particular power-saving states/modes for the end-user to select by evaluating and determining the end-user's desired outcome.

In another embodiment according to the present invention, the electronic device may be adapted to evaluate a plurality of end-user commands/selections. Evaluation of the end-user commands/selections enables the electronic device to suggest (prompt) an end-user to select from a plurality of appropriate selections for power-saving states/modes associated with the end-user's commands/selections being chosen.

In an embodiment according to the present invention, for example, if it is determined that the display entity is inactive, (the electronic device may be adapted to sense that the display entity is inactive), the electronic device may be adapted to autonomously/unilaterally enter the STAND-BY state/mode, the HIBERNATE state/mode, or the POWER-OFF state/mode, for example.

In an embodiment according to the present invention, the electronic device may be adapted to provide autonomous power-saving state/mode selection options by prompting an end-user to select a power-saving state/mode option. In an embodiment according to the present invention, the electronic device may enter the power-saving state/mode by default electronic device configuration. The electronic device may also prompt the end-user to enable or disable power-saving options by selecting an appropriate setting(s) from an electronic device menu.

In an embodiment according to the present invention, the electronic device may be adapted to determine whether an end-user is receiving/watching/viewing, etc., the multimedia-program information being displayed or broadcast. For example, the electronic device may be adapted to prevent unnecessary power consumption when an end-user has fallen asleep or when the end-user has left the physical area where the electronic device is displaying or broadcasting multimedia-program information by entering a power-saving mode.

In an embodiment according to the present invention, the electronic device may be adapted to prompt the end-user to press some button(s)/key(s), a sequence of button(s)/key(s), a password, an alphanumeric value displayed on the display device/entity (generated randomly by the electronic device), or a responsive value through a remote control device, for example, at predetermined or random intervals of time.

If the end-user fails to respond to the prompt within a particular period of time, (i.e., the end-user fails to press the appropriate a key(s)/button(s)), the electronic device may be adapted to enter a power-saving state/mode and/or shut-down power consuming operations in the order of highest power consumption, for example, turning off the display device/entity first, followed by lower power consuming components.

In an embodiment according to the present invention, the electronic device may also be adapted to turn off all electronic/electrical circuitry, and simultaneously, and autonomously enter one of the POWER-OFF state/mode, the STAND-BY state/mode, or the HIBERNATE state/mode. The electronic device may be adapted to prompt an end-user to enable or disable power-saving options by selecting from a plurality of menu option choices.

In an embodiment according to the present invention, the electronic device may be adapted to determine whether input signals from a multimedia-program distribution network are being received, either via a wire/cable or wirelessly. If it is determined that no signals are being received, the electronic device may autonomously enter one of the power-saving states/modes.

In an embodiment according to the present invention, the electronic device may also be adapted to switch-off the display device/entity, the decoding device/entity, and all other circuitry, associated respectively, with the display and decoding devices/entities, and enter one of the power-saving states/modes set forth above.

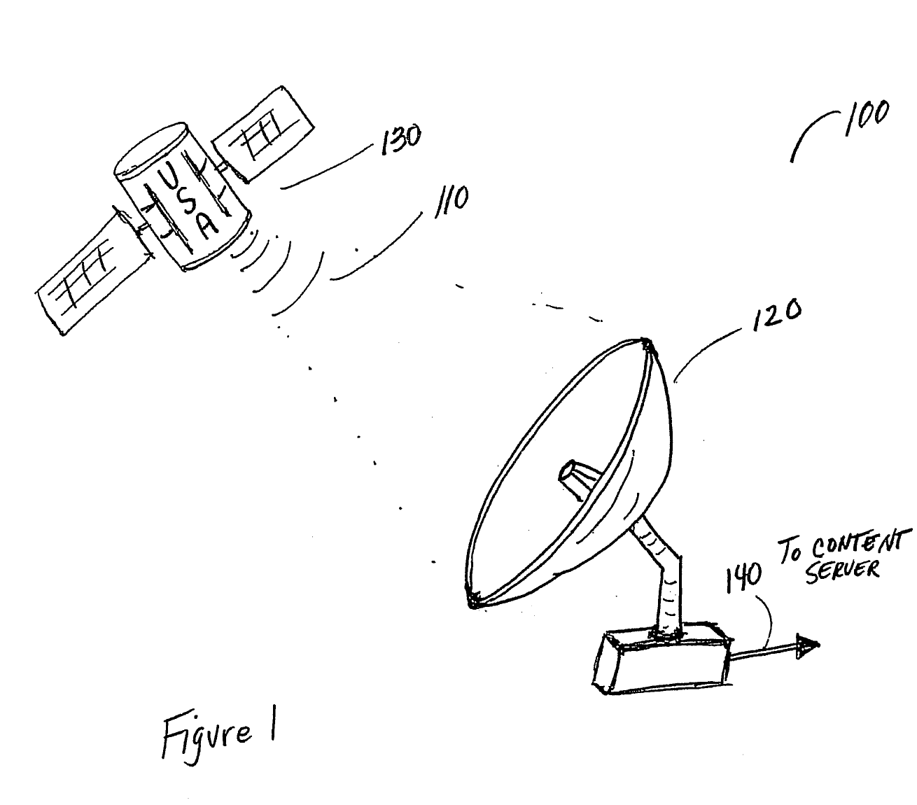

FIG. 1 is a perspective diagram 100 illustrating a satellite transmission/reception system in accordance with an embodiment of the present invention. In FIG. 1, a satellite 130 is illustrated transmitting multimedia-program information 110 to a satellite receiver 120. The satellite receiver 120 may be located proximate a service provider location. The satellite receiver 120 may comprise at least a receiving antenna and a tuner.

The service provider may comprise a cable television service provider, an Internet service provider, a radio service provider, and/or other multimedia-program service providers. The multimedia-program information received at the satellite receiver 120 may be conveyed to the service provider location via transmission cable 140. The multimedia-program information received at the satellite receiver 120 may also be conveyed to the service provider location via an optical fiber or wirelessly.

The satellite transmission/reception system illustrated in FIG. 1 may comprise a plurality of satellites 130 and a plurality of satellite receivers 120, wherein each satellite 130 may transmit a plurality of multimedia-program channels to a plurality of satellite receivers 120.

In an embodiment according to the present invention, the plurality of satellite receivers may be located in a different geographic location remote from the service provider location(s). The plurality of satellite receivers may be arranged in an array, wherein each satellite receiver may be pointed to and may receive transmissions from a particular satellite.

In an embodiment according to the present invention, at a satellite receiver array location, multimedia-program information for all channels that a service provider offers may be accumulated and encoded together for further satellite transmission to a plurality of remotely located respective service provider locations for further dissemination and distribution.

In accordance with an embodiment of the present invention, each of the plurality of multimedia-program transmissions may comprise a plurality of television channels, a plurality of radio channels, a plurality of Internet transmissions, etc. The plurality of multimedia-program transmissions may be conveyed to content servers residing at a plurality of service provider locations.

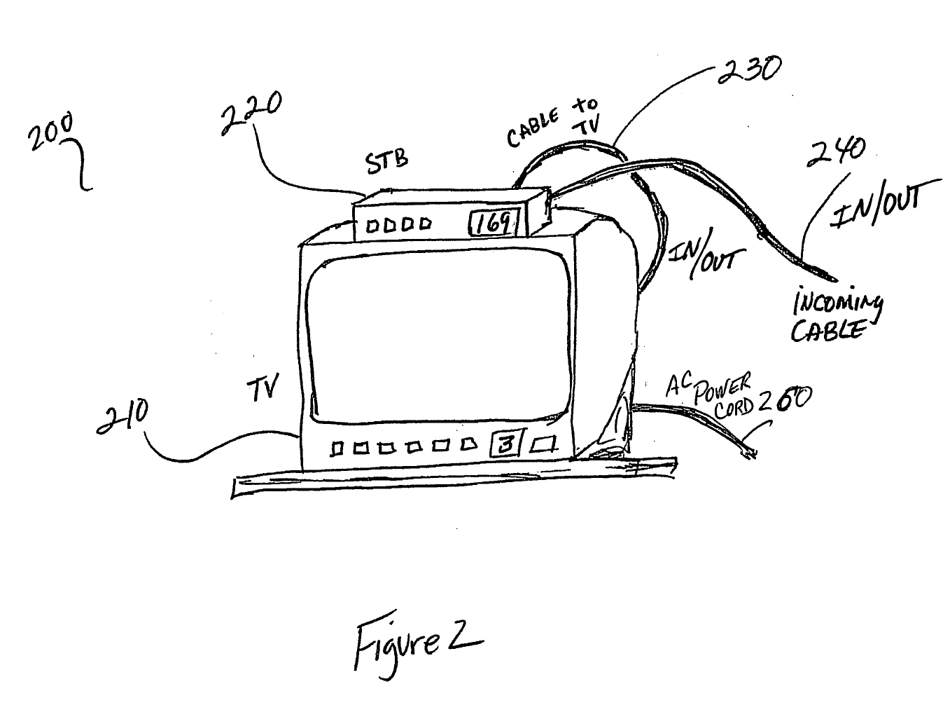

FIG. 2 is a perspective diagram 200 illustrating multimedia-program display components at an end-user location in accordance with an embodiment of the present invention. FIG. 2 illustrates a TV set 210 and an associated set-top-box (STB) 220. At the end-user location, a multimedia-program transmission may be received from an incoming cable 240. The incoming cable 240 may be directly or indirectly connected to a content server at a local service provider location.

The TV set 210 may also be provided with an alternating current (AC) power cord 260 which may be plugged into an electrical outlet to provide power to the TV set 210. The STB 220 may also comprise an AC power cord (not shown) providing power to the STB 220. Alternatively, power may also be supplied from at least one internal chargeable battery, etc.

The multimedia-program transmission transmitted through incoming cable 240 may be received at STB 220. From STB 220, another cable 230 may connect the STB 220 to the TV set 210. The multimedia-program transmission received at an end-user location may comprise every channel available for displaying or viewing that a service provider offers, whether the channel is subscribed to or not.

The multimedia-program transmission, because of the vast amounts of information being transmitted, (i.e., every channel the service provider offers), has a very large bandwidth. However, at an individual television set, for example, TV set 210, an end-user may only be able to watch at most 2 channels at a time, assuming that the TV set 210 is adapted to provide picture-in-picture (PIP) display.

Assuming that the multimedia-program transmission received at the end-user location comprises 600 to 1000 individual channels capable of being subscribed and viewed, for example, being simultaneously transmitted, then even if the end-user watches 2 channels at once via a PIP display device, more than 99% of the bandwidth and thus the multimedia-program information being transmitted to the end-user location is being wasted (i.e., not viewed).

In an embodiment according to the present invention, only the multimedia-program information that an end-user requests is transmitted to an end-user location. For example, if an end-user selects a channel to view, and the end-user is subscribed to the selected channel, then when the end-user selects the channel on the STB 220 to view, the STB 220 transmits a request for the multimedia-program information associated with that channel to the content server located at a geographically proximate (local) service provider location.

In response to the channel request, the content server may initiate transmission of the multimedia-program information associated with the selected channel to the end-user location. The STB 220 may also be adapted to determine whether the end-user is subscribed to the requested channel prior to sending the channel transmission request, wherein if the end-user is not subscribed, the STB may display a message of the TV set 210.

In another embodiment according to the present invention, the STB 220 may send the request to the content server, wherein the content server may be adapted to determine whether the end-user is subscribed to the requested channel, wherein if the end-user is not subscribed, the content server may transmit a message to the end-user location for display on the TV set 210.

If the end-user is subscribed to the selected channel, as determined by either the STB 220 or the local service provider's content server, then in response to the channel request, the content server may initiate transmission of the multimedia-program information associated with the selected channel.

If the end-user is not subscribed to the selected channel, then either the STB 220 or the local service provider's content server may cause a message to be displayed upon the TV set 210 informing the end-user that the selected channel has not been subscribed and is not currently authorized for viewing. The end-user may be prompted to initiate subscription or pay for viewing the selected channel (such as for example, pay-per-view PPV).

In another embodiment according to the present invention, if the end-user chooses to view two different channels at once, by activating the PIP function on the TV set 210, the STB 220 may request simultaneous transmission of both selected channels from the content server at the local service provider location.

In an embodiment according to the present invention, the amount of information being transmitted to a particular end-user location is significantly reduced over prior transmission methods. Prior transmission methods employed transmission of every channel that the service provider offers simultaneously to every end-user location, resulting in wasted bandwidth and transmission of vast amounts of unwanted and un-requested information to each end-user location.

Because the amount of multimedia-program information being transmitted to each end-user location, in accordance with an embodiment of the present invention, is significantly reduced, the bandwidth used to perform the multimedia-program transmission is also significantly reduced.

In an embodiment according to the present invention, cable theft may also be significantly reduced, if not totally eliminated, by only sending multimedia-program information that is requested by an end-user and by authenticating each end-user multimedia-program request. Cable theft may also be significantly reduced, if not totally eliminated, by securing a multimedia-program communication by applying encryption/decryption techniques to the multimedia-program content being transmitted, by employing derived session keys, by changing the employed session keys frequently, and by authenticating subscribed services.

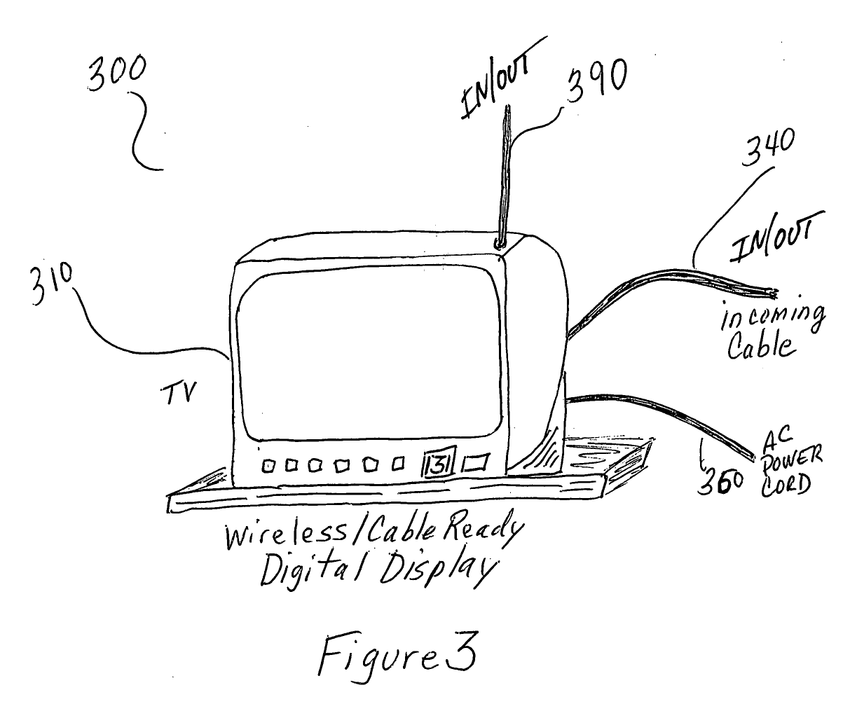

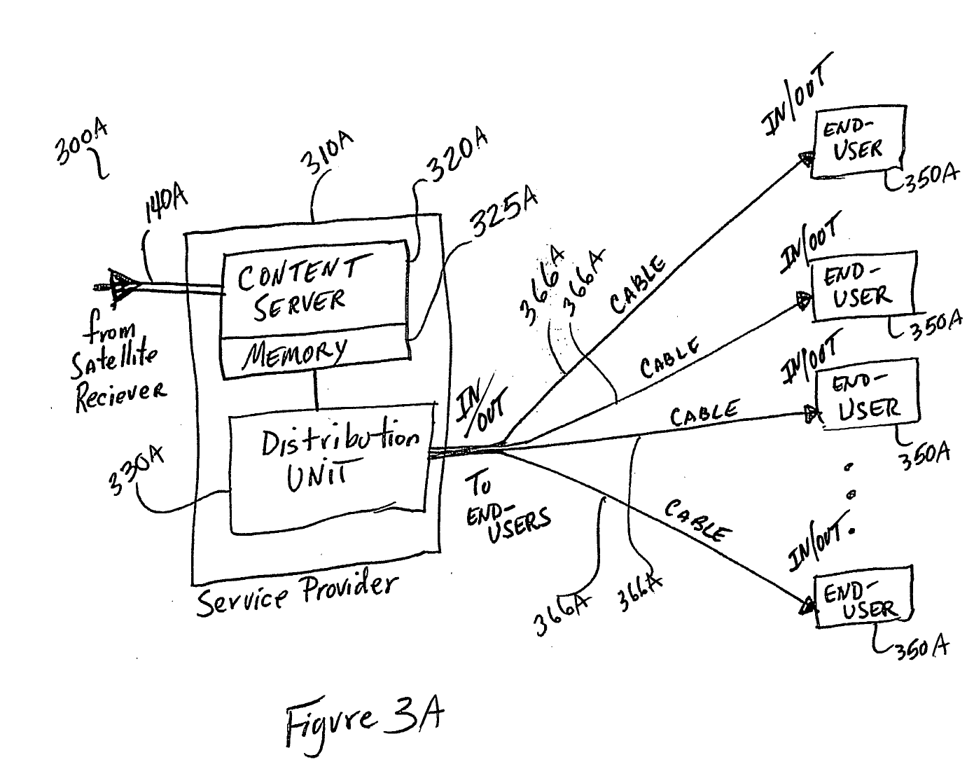

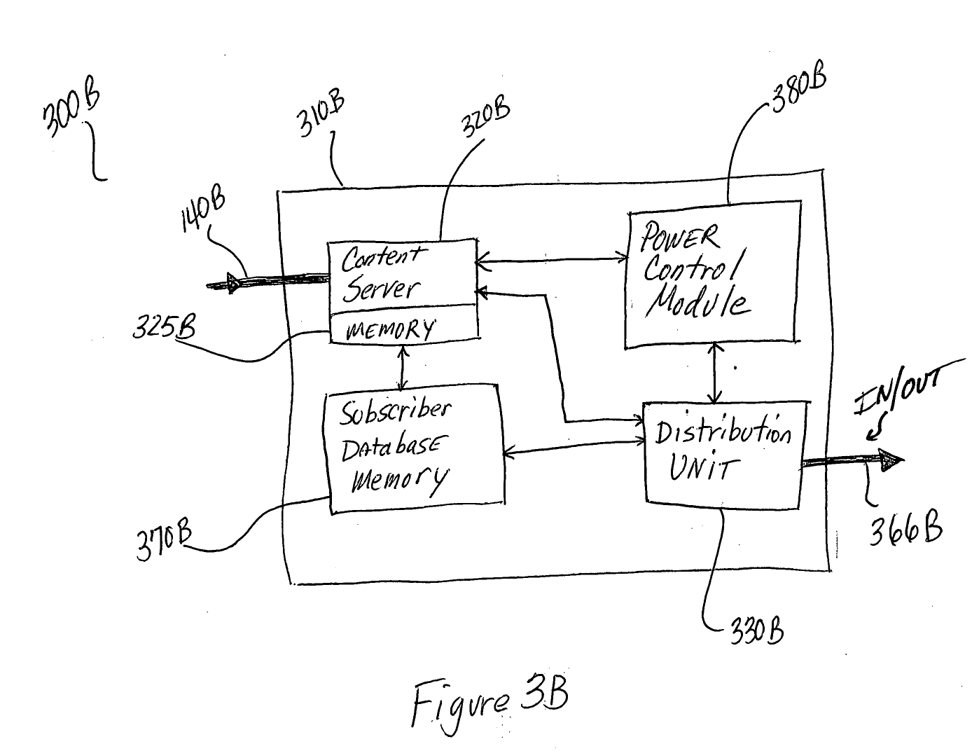

FIG. 3 is a perspective diagram illustrating a wireless cable-ready portable mobile multimedia-program decoder, transmitter, receiver, and display electronic device 300 in accordance with an embodiment of the present invention. FIG. 3 illustrates an electronic device, for example, a digital TV set 310. The digital TV set 310 may comprise an integrated decoder device/entity and an integrated display device/entity disposed within an interior of the electronic device. The integrated decoder device/entity and the integrated display device/entity may comprise an application specific integrated circuit (ASIC), a programmable logic device, or a processor/controller chip employed within the digital TV set 310.

In an embodiment according to the present invention, the integrated decoder device/entity may comprise a separate ASIC, programmable logic device, or processor/controller chip, and the integrated display device/entity may comprise another separate ASIC, programmable logic device, or processor/controller chip.

In an embodiment according to the present invention, at an end-user location, a multimedia-program transmission may be received at the electronic device from an incoming cable 340. The incoming cable 340 may be directly or indirectly connected to a content server at a local service provider location. The incoming cable 340 may provide two-way communication between an end-user location and a service provider location.

The incoming cable 340 may be removable from the electronic device 300. The electronic device 300 may also comprise an alternating current (AC) power cord 360 for powering the electronic device 300. The AC power cord 360 may also be removable from the electronic device.

In another embodiment according to the present invention, the multimedia-program transmission may be wirelessly received at the electronic device 300 via antenna 390. The electronic device 300 may be adapted to wirelessly receive multimedia-program transmissions from anywhere within a multimedia-program distribution network, i.e., within the wireless broadcast range of the nearest multimedia-program transmitter. The electronic device 300 may be adapted for two-way communication between the end-user location and the service provider location.

In an embodiment according to the present invention, the multimedia-program distribution network may comprise a network similar to a cellular telephone network, wherein a mobile electronic device, for example, digital TV set 310, may be enabled to seamlessly receive wireless broadcast multimedia-program transmissions while traveling throughout a multimedia-program broadcast region. The network may be enabled to seamlessly handoff transmission of the multimedia-program transmissions from one transmission tower to the next and from one base station to the next, according to an embodiment of the present invention.

In an embodiment according to the present invention, the AC power cord 360 may be removable, wherein the electronic device may be adapted to carry an on-board power supply, such as, for example, standard removable/replaceable non-rechargeable batteries, removable/rechargeable batteries, or an internal non-removable rechargeable battery pack or battery unit.

In an embodiment according to the present invention, the electronic device 300 may also be adapted to be operated via a direct current (DC) power supply such as, a 12-volt power system adapter associated with a vehicle or aircraft, or a 6-volt battery system associated with a watercraft, for example.

The electronic device 300 may also be adapted to communicate with the wireless multimedia-program distribution network to request, receive, decode, store, and display or broadcast multimedia-program information. The multimedia-program information may comprise video, audio, photographs, text, documents, and wireless telephony, for example. The multimedia-program transmissions transmitted to the electronic device may be received at an integrated decoder/display device/entity.

In an embodiment according to the present invention, only the multimedia-program information that an end-user requests may be transmitted to the electronic device 300. For example, if the end-user selects a channel to receive, and the end-user is subscribed to the selected channel, then when the end-user selects the channel on the electronic device 300 to receive, the electronic device 300 may wirelessly transmit a request for the multimedia-program information associated with that channel to a content server located at a geographically proximate (local) service provider location via a wireless transmission infrastructure. In response to the channel request, the content server may initiate wireless transmission of the multimedia-program information associated with the selected channel via the wireless transmission infrastructure to the electronic device 300.

In an embodiment according to the present invention, the electronic device 300 may also be adapted to determine whether the end-user is subscribed to the requested channel prior to sending the channel transmission request, wherein if the end-user is not subscribed, the electronic device may broadcast a message of the end-user informing the end-user of the same.

In an embodiment according to the present invention, the electronic device 300 may send the request to the content server, wherein the content server may be adapted to determine whether the end-user is subscribed to the requested channel, wherein if the end-user is not subscribed, the content server may transmit a message to the electronic device informing the end-user of the same.

If the end-user is subscribed to the selected channel, as determined by either the electronic device 300 or the local service provider's content server, then in response to the channel request, the content server may initiate wireless transmission of the multimedia-program information associated with the selected channel to the electronic device 300.

If the end-user is not subscribed to the selected channel, then either the electronic device 300 or the local service provider's content server may cause a message to be broadcast by the electronic device 300 informing the end-user that the selected channel has not been subscribed and is not currently authorized for receiving. The message may comprise and audio message, a visual message, or a combination, audio/video message. The end-user may be prompted to initiate subscription or pay for receiving the selected channel (such as, for example, pay-per-view PPV).

FIG. 3A is a block diagram illustrating a multimedia-program distribution network 300A in accordance with an embodiment of the present invention. The multimedia-program distribution network 300A illustrated in FIG. 3A may comprise a local service provider system 310A.

The local service provider system 310A may comprise at least a content server 320A and a distribution unit 330A. The content server 320A may receive a plurality of multimedia-program transmissions via transmission cable 140A from a satellite receiver, for example, satellite receiver 120, as illustrated in FIG. 1. The content server 320A may also receive a plurality of multimedia-program transmissions via an optical fiber or wirelessly from a satellite receiver.

In an embodiment according to the present invention, the content server 320A may comprise a storage unit memory 325A for receiving and storing multimedia-program information. The content server 320A may also be adapted to provide on-demand access to streaming media transmissions (channels) being received from the satellite receiver 120. The content server 320A may be adapted to validate and authorize channel requests received from a plurality of end-users' electronic devices from a plurality of end-users' locations 350A. The content server 320A may also be adapted to authenticate end-users' electronic devices and derive session keys (encryption/decryption) to secure the communication between the electronic devices and a network's multimedia-program transmission equipment.

In an embodiment according to the present invention, a channel may be selected for receiving at an end-user location 350A. The end-user's electronic device, for example, as illustrated in FIGS. 2 and 3, may transmit a channel request via cable 366A or wirelessly via a wireless transmission to the service provider location 310A. The channel request may be received at a distribution unit 330A, which may convey the request to the content server 320A. Alternatively, the channel request may be received at the content server 320A.

FIG. 3B is a block diagram illustrating a multimedia-program distribution, power control and power monitoring system 300B in accordance with an embodiment of the present invention. The multimedia-program distribution, power control and power monitoring system 300B illustrated in FIG. 3B may comprise a local service provider system 310B. The local service provider system 310B may comprise at least a content server 320B and a distribution unit 330B. The content server 320B may receive the plurality of multimedia-program transmissions via transmission cable 140B from a satellite receiver, for example, satellite receiver 120, as illustrated in FIG. 1. The content server 320B may also receive the plurality of multimedia-program transmissions via an optical fiber or wirelessly from a satellite receiver.

The content server 320B may comprise a storage unit memory 325B for receiving and storing multimedia-program transmission information. The content server 320B may also be adapted to provide on-demand access to streaming media transmissions (channels) being received from the satellite receiver 120.

The content server 320B may be adapted to validate and authorize channel requests received from the plurality of end-users locations by accessing a subscriber database memory 370B. The subscriber database memory 370B may comprise end-user electronic device information, end-user channel subscription information, end-user spending limit information, end-user blocked channel information, end-user identity information for authentication, etc.

In an embodiment according to the present invention, as illustrated in FIG. 3B, a channel may be selected for viewing at an end-user location. The end-user's electronic device, for example, as illustrated in FIGS. 2 and 3, may transmit a channel request via cable 366B or wirelessly via a wireless transmission to the service provider location 310B. The channel request may be received at a distribution unit 330B, which may convey the request to the content server 320B. Alternatively, the channel request may be received directly at the content server 320B.

The content server 320B may process the channel request. Processing the channel request at the content server 320B may comprise analyzing and evaluating the channel request. Analyzing and evaluating the channel request may comprise determining from the channel request end-user electronic device information, etc., and thus, associated information related to the end-user requesting the channel.

The channel request may be compared with a database of subscriber information 370B, wherein if it is determined that channel is subscribed the channel request is initiated. Initiation of the channel request may comprise transmitting the requested multimedia-program information to the electronic device at the end-user location.

If it is determined that the channel is not subscribed, the content server 320B may transmit a message to the electronic device informing the end-user that the channel requested is unsubscribed and not unauthorized for viewing. The transmitted message may also comprise a prompt to cause the end-user to subscribe to the channel and/or pay for viewing the channel, such as pay-per-view (PPV).

In an embodiment according to the present invention, the content server 320B may transmit a message to the electronic device informing the end-user that the selected channel is unavailable for access, for example, because the channel is unavailable from the satellite or the channel is restricted for select end-users only.

In another embodiment, the content server 320B may authenticate the electronic device after entering POWER-ON state/mode. Similarly the electronic device may initiate the authentication process after entering the POWER-ON state/mode. The content server 320B and the electronic devices may derive separate session keys at frequent time intervals in order to encrypt/decrypt the contents of present and future communications and multimedia-program information and data. Encryption/decryption may also prevent multimedia-program theft.

In an embodiment according to the present invention, the distribution unit 330B may comprise a plurality of transmission heads. The transmission heads may comprise mechanical, electrical, electronic switches or relays adapted to maintain continuous communication with the electronic device at a particular end-user location.

The service provider location 310B may also comprise a power control module 380B. The power control module 380B may be adapted to request, evaluate, and transmit power control signals to the electronic device regarding instantaneous or average power consumption, an instantaneous or average power level, and an amount of power remaining in the electronic devices at any particular instant, if powered by an on-board power supply, for example.

The power control module 380B at the service provider location 310B may be adapted to transmit a power information request to the electronic device, wherein the electronic device may be adapted to respond to the power information request by transmitting the requested power information corresponding to the electronic device to the power control module 380B at the service provider location 310B.

In an embodiment according to the present invention, the power information request, and response thereto, may be adapted to ride a carrier signal associated with a multimedia-program transmission or may be encoded in other communications between the service provider location 310B and the electronic device.

In an embodiment according to the present invention, the power control module 380B may be adapted to evaluate the power information response from the electronic device, wherein in response to the evaluated power information response, the power control module 380B may be adapted to issue power-saving commands to the electronic device.

In an embodiment according to the present invention, the power control module 380B may, for example, command the electronic device to inform an end-user of a low power remaining situation. The power control module 380B may command the electronic device to prompt the end-user to select a power-saving state/mode from a power-saving state/mode selection menu. The power control module 380B may command the electronic device to determine whether an end-user is present by prompting the end-user to press a button(s)/key(s) on a remote control device, wherein if no appropriate response is received from an end-user within a particular time limit, the power control module 380b may be adapted to autonomously command the electronic device to enter a power-saving state/mode as set forth above.

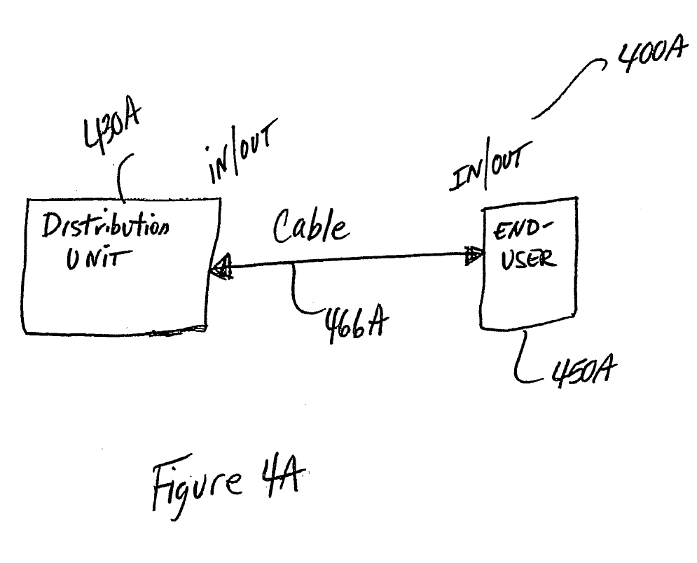

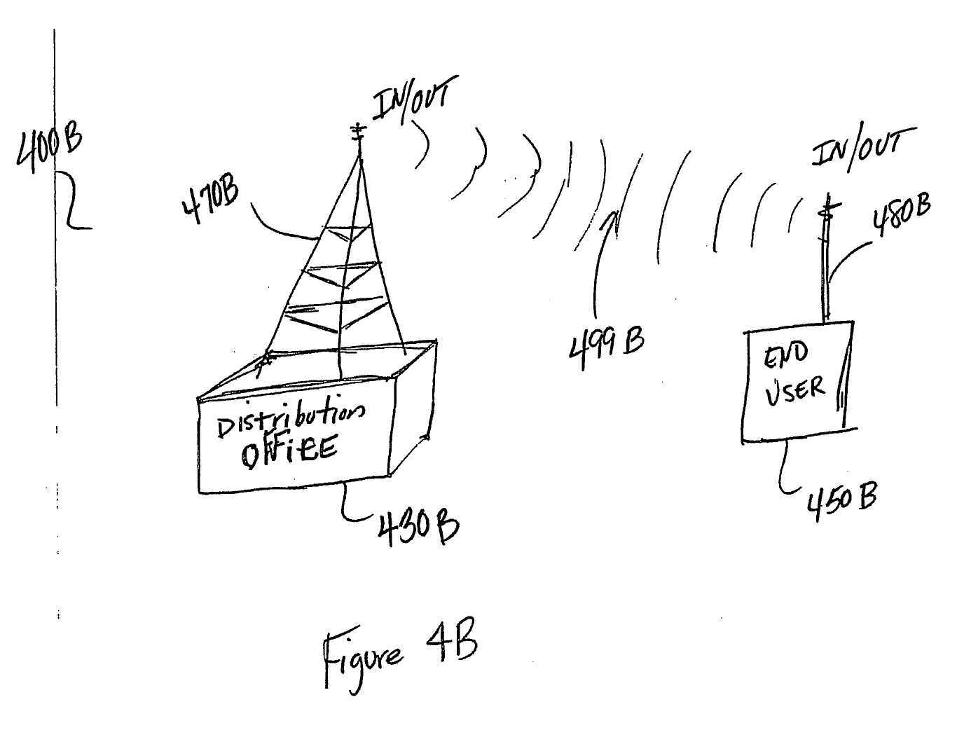

FIG. 4A is a block diagram illustrating a cable multimedia-program distribution network 400A in accordance with an embodiment of the present invention. FIG. 4A illustrates a wired multimedia-program distribution network 400A. In the wired multimedia-program distribution network 400A, according to an embodiment of the present invention, each respective end-user 450A may be connected (hard wired) to a transmission head of the distribution unit 430A at the local service provider location via a cable 466A. The wired communication medium may be, but is not limited to one of Analog RF, Ethernet, etc.

FIG. 4B is a block diagram illustrating a wireless multimedia-program distribution network 400B in accordance with an embodiment of the present invention. FIG. 4B illustrates a wireless multimedia-program distribution network 400B wherein each respective end-user 450B may be wirelessly connected to a transmission head of the distribution unit in a distribution office 430B at the local service provider location via over-the-air (OTA) transmissions 499B. The wireless communication medium may be but is not limited to Institute of Electrical and Electronics Engineers (IEEE) 802.11 wireless local area network (LAN) standard, Bluetooth, code division multiple access (CDMA), Global System for Mobile Communications (GSM), WiMax, etc.

In an embodiment according to the present invention, the bandwidth and multimedia-program information being transmitted from the distribution office 430B to each individual end-user 450B may be significantly reduced in comparison to prior multimedia-program distribution systems.

In an embodiment according to the present invention, instead of transmitting every channel that the multimedia-program service provider offers to every individual end-user 450B, only the selected multimedia-program information or a particular selected channel is transmitted to the individual end-users 450B. The significant reduction in bandwidth being transmitted makes it possible to transmit the multimedia-program information wirelessly over-the-air (OTA) instead of using a cable.

In an embodiment according to the present invention, the distribution office may be provided with a transmission tower 470B. The transmission tower 470B may be adapted to transmit individualized multimedia-program information, (i.e., a selected channel) to each individual end-user's STB. Each STB at each end-user location 450B may also be provided with an antenna 480B.

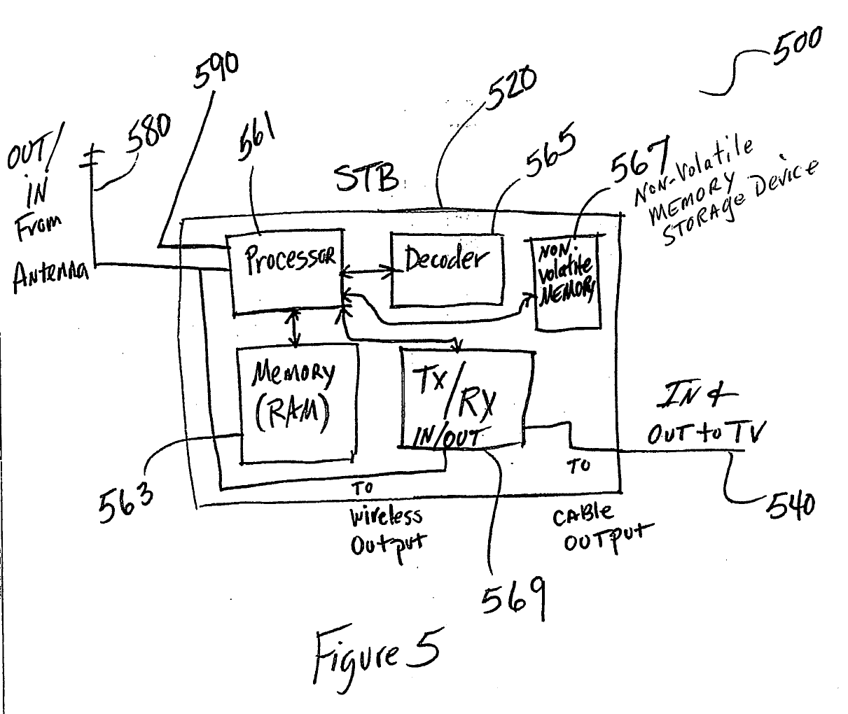

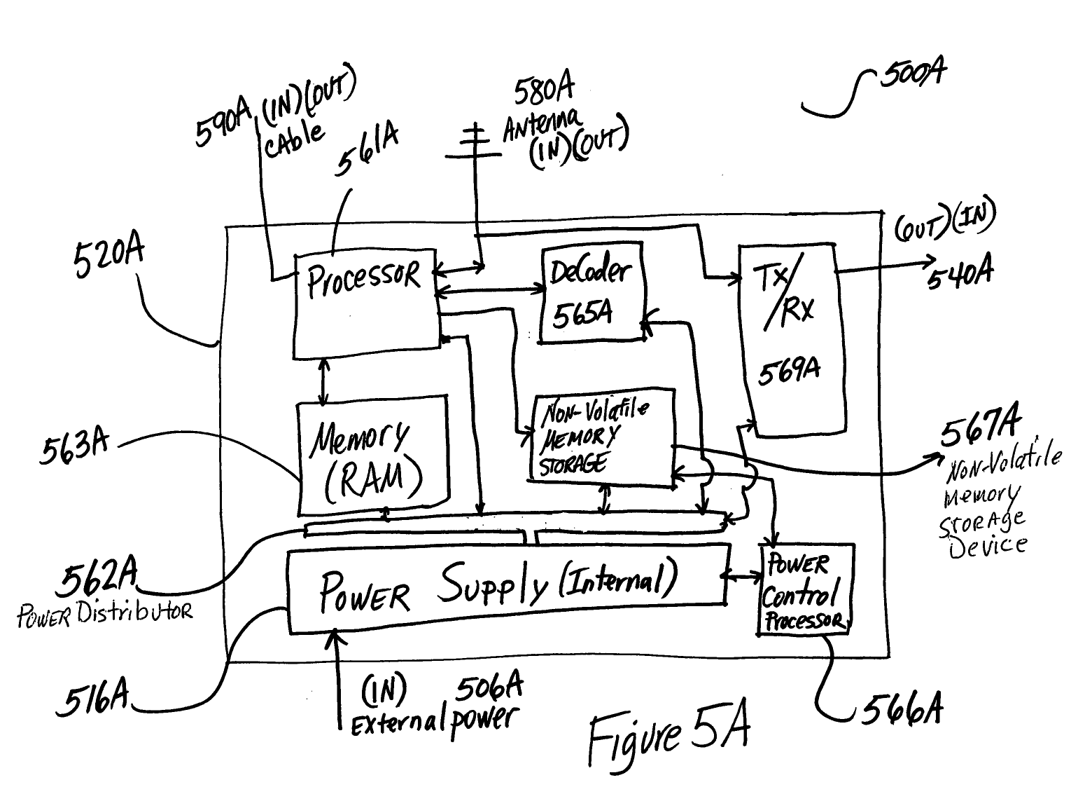

FIG. 5 is a block diagram 500 illustrating a wireless set-top-box (STB) multimedia-program unit in accordance with an embodiment of the present invention. FIG. 5 illustrates a wireless STB 520 comprising an antenna 580 for communicating with a wireless multimedia-program distribution office. The wireless communication between the STB and the wireless multimedia-program distribution office may comprise two-way communication.

The wireless STB 520 may also comprise a processor 561, a random access memory 563, an audio/video decoder 565, a non-volatile memory storage device 567, and a combination transmitter/receiver 569, for example. The wireless STB 520 may also comprise a cable output 540 providing transmission of the received decoded multimedia-program information to a TV set or another display apparatus. The output 540 may also be wireless for communicating with wireless enabled TVs or other wireless enabled display apparatus.

In an embodiment according to the present invention, an end-user may select to view a channel of multimedia-program information. The end-user selection may be made remotely via a remote control device, wherein the end-user may enter a channel number remotely selecting the channel at the wireless STB 520. The wireless STB 520, in response to the end-user channel selection, may determine whether the end-user is subscribed and authorized to view the selected channel.

In an embodiment according to the present invention, in response to the end-user channel selection, the STB 520 may transmit the end-user channel selection to the content server or the distribution unit at the service provider location. The content server or the distribution unit at eth service provider location may determine whether the end-user is subscribed and authorized to view the selected channel and whether to convey the multimedia-program information to the STB 520.

If the end-user is unsubscribed or unauthorized to view the selected channel, then the wireless STB may cause a message to be displayed at the display device informing the end-user that the channel is unsubscribed or unauthorized for viewing. The message may comprise an audio message, a visual message, or a combination audio/video message. Wireless STB 520 may also prompt the end-user to subscribe or order the selected channel.

In an embodiment according to the present invention, upon receiving a channel selection request from an end-user, the wireless STB 520 may wirelessly transmit the channel selection request to the distribution unit at the local service provider location.

The transmission request may be transmitted by a combination transmitter/receiver 569. In an embodiment according to the present invention, the transmitter and receiver may be separate components, wherein a wireless transmitter wirelessly transmits the channel request to the distribution unit at the local service provider location and a wireless receiver wirelessly receives multimedia-program information and other communication from the service provider location. In an embodiment according to the present invention, one of the transmitter and receiver may be wired, while the other of the transmitter and receiver may operate wirelessly.

In another embodiment according to the present invention, after entering the POWER-ON state/mode, the STB 520 may initiate an authentication process. At the local service provider location, the channel request may be processed. In an embodiment according to the present invention, the channel request may be evaluated, validated, and authorized at one of the distribution unit or the content server at the service provider location.

If the channel request is validated, the content server may initiate transmission of the multimedia-program information associated with the requested channel. Transmission of the requested channel may be carried out wirelessly, wherein the wireless transmitter located at the distribution office at the service provider location may wirelessly transmit the multimedia-program information to the wireless STB 520.

At the STB 520, the multimedia-program transmission may be received at antenna 580 and conveyed to processor 561. The antenna 580 of the STB may be adapted for two-way communication, i.e., both receiving and transmitting. The multimedia-program transmission may also be received through a wireline connection 590. Further, channel requests may be transmitted by antenna 580 or through a wireline connection 590.

In an embodiment according to the present invention, processor 561 may convey the multimedia-program transmission to audio/video decoder 565. The audio/video decoder 565 may be a combination unit or two separate units. The multimedia-program transmission may be decoded and transmitted via cable output 540 to electronic device for display.

FIG. 5A is a block diagram 500A illustrating a wireless electronic device multimedia-program unit (WEDMU) 520A in accordance with an embodiment of the present invention. FIG. 5A illustrates the WEDMU 520A comprising an antenna 580A for communicating with a wireless multimedia-program distribution office. The WEDMU may comprise an integrated circuit, a Peripheral Component Interconnect (PCI) card, Accelerated Graphics Port (AGP) card, a digital logic circuit on a printed circuit board, a self contained processing unit or chip, such as, a dual in-line package (DIP) chip, a pin-grid array (PGA) chip, a single in-line package (SIP) chip, or another type of logical configuration.

In an embodiment according to the present invention, the WEDMU 520A may comprise a processor 561A, a random access memory 563A, an audio/video decoder 565A, a non-volatile memory storage device 567A, and a combination transmitter/receiver 569. The WEDMU 520A may also comprise a cable output 540A providing transmission of received decoded multimedia-program information to a display apparatus. The output 540A may also be wireless for wirelessly communicating with a wireless enabled display apparatus.

The WEDMU 520A may comprise an internal power supply apparatus 516A. The internal power supply apparatus 516A may comprise a removable battery containment and connection apparatus, a rechargeable battery containment and connection apparatus, or an external power source adapter unit 506A. The external power source adapter unit 506A may comprise a connector for receiving an AC power cord or an AC adapter transformer unit.

In an embodiment according to the present invention, the internal power supply apparatus 516A may also be connected to a power distributor 562A. The power distributor 562A may connect to each component of the WEDMU 520A and may distribute power from the power supply apparatus 516A to all of the electrical/electronic components according to the power need. The internal power supply apparatus 516A may also be operatively connected to a power control processor 566A. The power control processor 566A may be adapted to wirelessly communicate with the power control module 380B, as illustrated in FIG. 3B, located at the service provider location.

The power control processor 566A may be adapted to monitor and store power information corresponding to the electronic device, the WEDMU 520A, and an associated display/broadcast apparatus. A power consumption and use log may be created in non-volatile memory storage device 576A. The power consumption and use log may be evaluated to determine power-saving states/modes and situations where power-saving states/modes may be employed. The power consumption and use log may also be evaluated to troubleshoot the electronic device, the WEDMU 520A, and an associated display apparatus.

In an embodiment according to the present invention, an end-user may select to view a channel. The end-user selection may be made remotely via a remote control device, wherein the end-user may enter a channel number to remotely select the channel, and wherein the channel request may be received at the WEDMU 520A. The WEDMU 520A, in response to the end-user channel selection, may determine whether the end-user is subscribed and authorized to view the selected channel.

In an embodiment according to the present invention, in response to the end-user channel selection, the WEDMU 520A may transmit the channel selection to the content server or the distribution unit via the antenna 580A or cable 590A. The content server or the distribution unit may determine whether the end-user is subscribed and authorized to view the selected channel and whether to convey the multimedia-program information to the WEDMU 520A.

If the end-user is unsubscribed or unauthorized to view the selected channel, then the WEDMU 520A may cause a message to be displayed at a display device informing the end-user that the channel is unsubscribed or unauthorized for viewing. The message may comprise an audio message, a visual message, or a combination audio/video message. The WEDMU 520A may also prompt the end-user to subscribe or order the selected channel.

In an embodiment according to the present invention, upon receiving a channel selection request from an end-user, the WEDMU 520A may wirelessly transmit the channel selection request to the distribution unit of the content server at the local service provider location.

The channel selection request may be transmitted by the combination transmitter/receiver 569A. In an embodiment according to the present invention, the transmitter and receiver may be separate components, wherein a wireless transmitter may wirelessly transmit the channel selection request to the distribution unit or the content server at the local service provider location and a wireless receiver may wirelessly receive the associated multimedia-program information at the end-user location. In an embodiment according to the present invention, one of the transmitter and receiver may operate wirelessly while the other may operate via a wired connection.

In another embodiment according to the present invention, after entering a POWER-ON state/mode, the WEDMU 520A may initiate an authentication process.

At the local service provider location, the channel request may be processed. In an embodiment according to the present invention, the channel request may be evaluated, validated, and authorized at one of the distribution unit or the content server.

If the channel request is validated, the content server may initiate transmission of the multimedia-program information associated with the requested channel. Transmission of the requested channel may also be carried out wirelessly, wherein a wireless transmitter located at the distribution office of the local service provider may transmit the multimedia-program information to the WEDMU 520A at the end-user location.

At the WEDMU 520A, the multimedia-program transmission may be received at antenna 580A and conveyed to processor 561A. The multimedia-program transmission may also be received through a wireline connection 590A in an embodiment according to the present invention. The processor 561A may convey the multimedia-program transmission to audio/video decoder 565A. The audio/video decoder may be a combination unit or two separate units in embodiment according to the present invention. The multimedia-program transmission may be decoded and transmitted via cable output 540A to the electronic device for display in an embodiment according to the present invention.

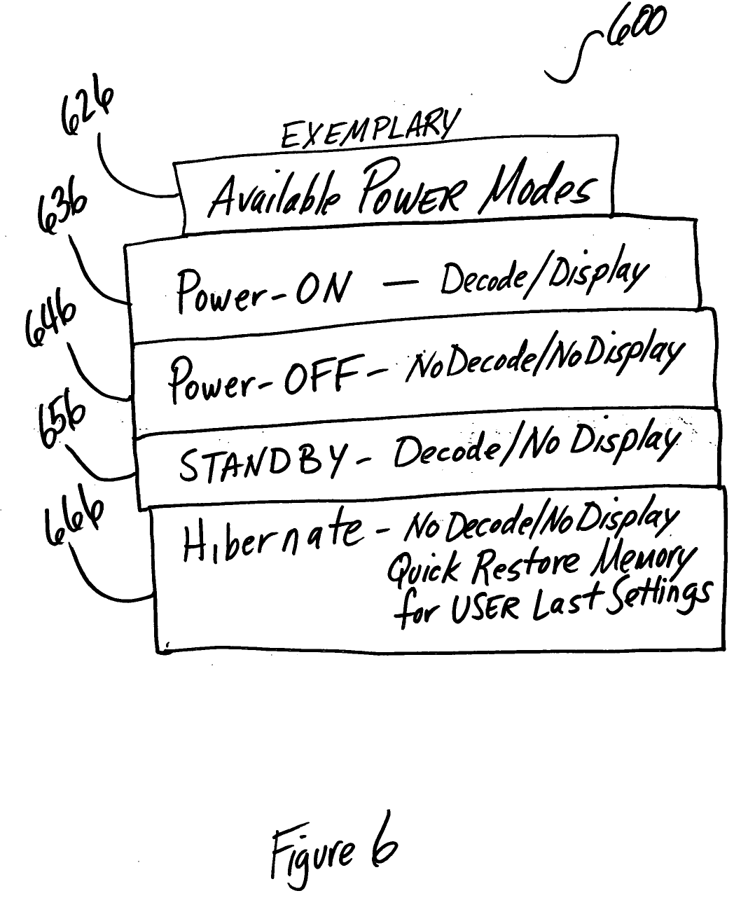

FIG. 6 is a diagram 600 illustrating a plurality of suggested and not limited to, power states/modes 626 which may be applicable in an STB or a WEDMU according to an embodiment of the present invention. In an embodiment according to the present invention, an STB or a WEDMU may be in a POWER-ON state/mode 636, wherein both the decoding device/entity and the display device/entity may be powered on.

In another embodiment according to the present invention, an STB or a WEDMU may be in a POWER-OFF state/mode 646, wherein both the decoding device/entity and the display device/entity may be powered off.

In another embodiment according to the present invention, an STB or a WEDMU may be in a STAND-BY state/mode 656, wherein the decoding device/entity may be powered on and the display device/entity may be powered off.

In an embodiment according to the present invention, an STB or a WEDMU may be in a HIBERNATE state/mode 666, wherein both the decoding device/entity and the display device/entity may powered off, but an end-user's last settings and/or preferences may be rapidly restorable from a quick restore memory consuming only a small amount of power to maintain the end-user's last settings and/or preferences.

The quick restore memory may comprise random access memory in an embodiment according to the present invention. In another embodiment according to the present invention, the quick restore memory may comprise a FLASH memory or a secondary memory storage device, such as, a hard drive, wherein power consumption to maintain the end-user's last setting and/or preferences may not be necessary.

Aspects of the present invention may also be found in power-saving states/modes and power-saving methods applicable for use in personal multimedia-program recording applications. A personal multimedia-program recording application may be defined as at least one end-user issued command to a consumer electronic device, such as, for example, an STB, a WEDMU, or a digital TV product, to record a requested channel selection or multimedia-program information being broadcast at a later time.

POWER-ON state/mode: According to an embodiment of the present invention, in the POWER-ON state/mode, the electronic device may be powered up. The electronic device may comprise a decoding device/entity, a processing device/entity, and a display or broadcast device/entity. The display device/entity may be powered on, i.e., ready to display or currently displaying multimedia-program information. The decoding device/entity in the electronic device may also be powered on, wherein decoding of received multimedia-program information may be occurring prior to or concurrent with displaying the multimedia-program information.

The POWER-ON state/mode may consume a maximum amount of power in overall operations of the electronic device. The electronic device may enter the POWER-ON state/mode when power is initially applied to the electronic device. Alternatively, the POWER-ON state/mode may occur when a switch is employed to turn on the electronic device, enabling power flow and power consumption within the electronic device.

POWER-OFF state/mode: According to an embodiment of the present invention, in the POWER-OFF state/mode, the decoding device/entity and the display device/entity of the electronic device may both be powered off. The POWER-OFF state/mode consumes no power. The electronic device may enter the POWER-OFF state/mode after being physically switched off.

STAND-BY state/mode: According to an embodiment of the present invention, in the STAND-BY state/mode, the display device/entity may be powered off and the decoding device/entity may remain powered on. The electronic device may appear to be turned off, because the display device/entity may not be displaying or broadcasting any multimedia-program information. The display circuitry may be powered off, wherein the electronic device may be adapted to reduce power consumption.

In the STAND-BY mode, the decoding circuitry may be powered on, wherein the electronic device may be receiving, decoding, and storing multimedia-program information for later playback. The received/decoded multimedia-program information may be stored in a non-volatile memory storage device, such as a hard drive or other secondary storage devices.

In an embodiment according to the present invention, the multimedia-program information may be stored prior to being decoded during the STAND-BY state/mode and decoded at playback.

In another embodiment according to the present invention, the received multimedia-program information may be decoded upon receiving, prior to storage, and played directly from storage in the decoded format.

In the STAND-BY state/mode, all functions related to the electronic device may be accessible, except for the display/broadcast functions, for example, which may consume more power than other electronic device functions. In an embodiment according to the present invention, for example, Personal multimedia-program recording may be commenced and may continue autonomously while the electronic device is in the STAND-BY state/mode.

HIBERNATE state/mode: According to an embodiment of the present invention, in the HIBERNATE state/mode the display device/entity and the decoding device/entity may both be switched off. However, some minimal amount of circuitry of the electronic device may remain on and operational to maintain intact in a volatile memory, such as for example, random access memory (RAM), an end-user's last settings and/or preferences, fro example, wherein when the electronic device emerges from the HIBERNATE state/mode, i.e., is switched on or powered on from the HIBERNATE state/mode, the end-user's last settings may be restored.

In an embodiment according to the present invention, during HIBERNATE state/mode, the end-user's last settings and/or preferences may be stored in a non-volatile memory, wherein all of the circuits, except the “wakeup-related” circuits may be switched off after storing the end-user's last settings and/or preferences.

In an embodiment according to the present invention, by saving the end-user's last settings and/or preferences in non-volatile memory, the end-user may avoid re-entering a username/password, re-selecting a display or broadcast option, or re-entering previous settings and/or preferences, for example.

In an embodiment according to the present invention, the electronic device may enter the HIBERNATE state/mode when it is determined that no end-user is present to receive the displayed or broadcast multimedia-program information or the end-user display apparatus is inactive.

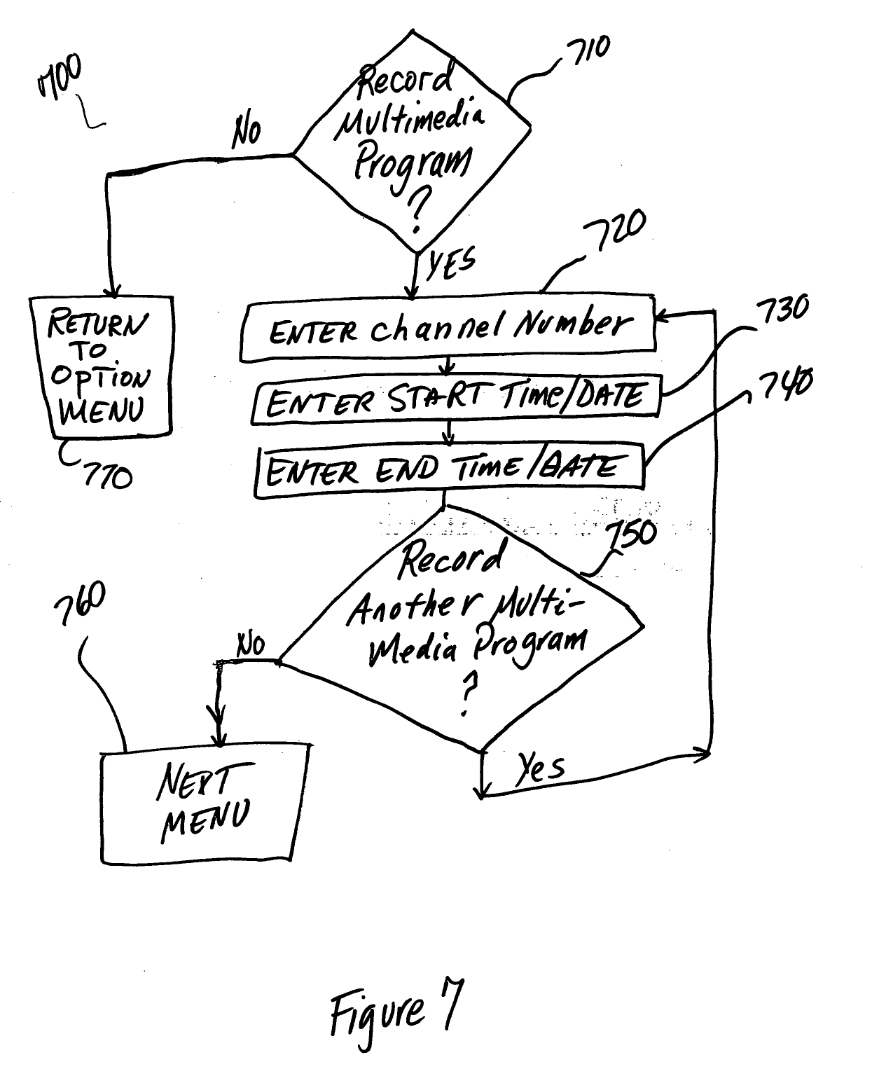

FIG. 7 is a flow diagram illustrating a method of personal multimedia-program recording using an electronic device according to an embodiment of the present invention. Personal multimedia-program recording may comprise an electronic device prompting an end-user to answer whether the end-user desires to record a requested multimedia-program 710. If the end-user selects a negative response, i.e., the end-user does not desire to record a multimedia-program or has selected the record option accidentally, the electronic device may return to an option selection menu 770.

In an embodiment according to the present invention, the end-user may select a record option from an option selection menu comprising a plurality of electronic device options, such as, for example, record, search, delete, erase, play, pause, store, fast forward, reverse, delete commercials, select a chapter, select a language, etc.

If the end-user selects an affirmative response, i.e., the end-user desires to record a multimedia-program, the end-user may be prompted to enter the channel number corresponding to the requested multimedia-program 720. The end-user may also be prompted to enter a start time and date of the requested multimedia-program 730. For example, the end-user may enter on a keypad or on a remote control device, 10:00 AM Apr. 30, 2004, corresponding to the start time and date of a first multimedia-program being broadcast the following day from 10:00 AM to 11:00 AM. The end-user may also be prompted to enter an end time and date of the requested multimedia-program 740. The end-user may enter on a keypad or on a remote control device, 11:00 AM Apr. 30, 2004, corresponding to the end time and date of a first multimedia-program being broadcast the following day from 10:00 AM to 11:00 AM.

In an embodiment according to the present invention, the end-user may also provide the start time of recording as the current date and time. In an embodiment according to the present invention, the end-user may terminate a recording process anytime the end-user desires by pressing a specific key(s) on a remote control device or by selecting a terminate record option from the option selection menu.

In an embodiment according to the present invention, multiple multimedia-programs may be recorded for subsequent playback. The electronic device may prompt the end-user to answer whether the end-user desires to record another multimedia-program 750. If the end-user selects an affirmative response, i.e., the end-user desires to record another multimedia-program, the end-user may be prompted to enter the channel number corresponding to the additional requested multimedia-program 720.

The end-user may also be prompted to enter a start time and date of the additional requested multimedia-program 730. For example, the end-user may enter on a keypad or on a remote control device, 2 PM Apr. 30, 2004, corresponding to the start time and date of a second multimedia-program being broadcast the same day as the first multimedia-program from 2:00 PM to 4:00 PM. The end-user may also be prompted to enter an end time and date of the additional requested multimedia-program 740. The end-user may enter on a keypad or on a remote control device, 4 PM Apr. 30, 2004, corresponding to the end time and date of the second multimedia-program being broadcast the same day from 2:00 PM to 4:00 PM.

The electronic device may prompt the end-user to answer whether the end-user desires to record another multimedia-program 750. If the end-user selects a negative response, i.e., the end-user does not desire to record another multimedia-program, the electronic device may advance to another program menu 760.

In an embodiment according to the present invention, the end-user may be prompted to record at least one or a plurality of multimedia-programs by interacting with the STB, the WEDMU, or another electronic device at a time prior to the multimedia-program being broadcast, thus removing the necessity of the end-user to be physically present at broadcast time to initiate the recording procedure.

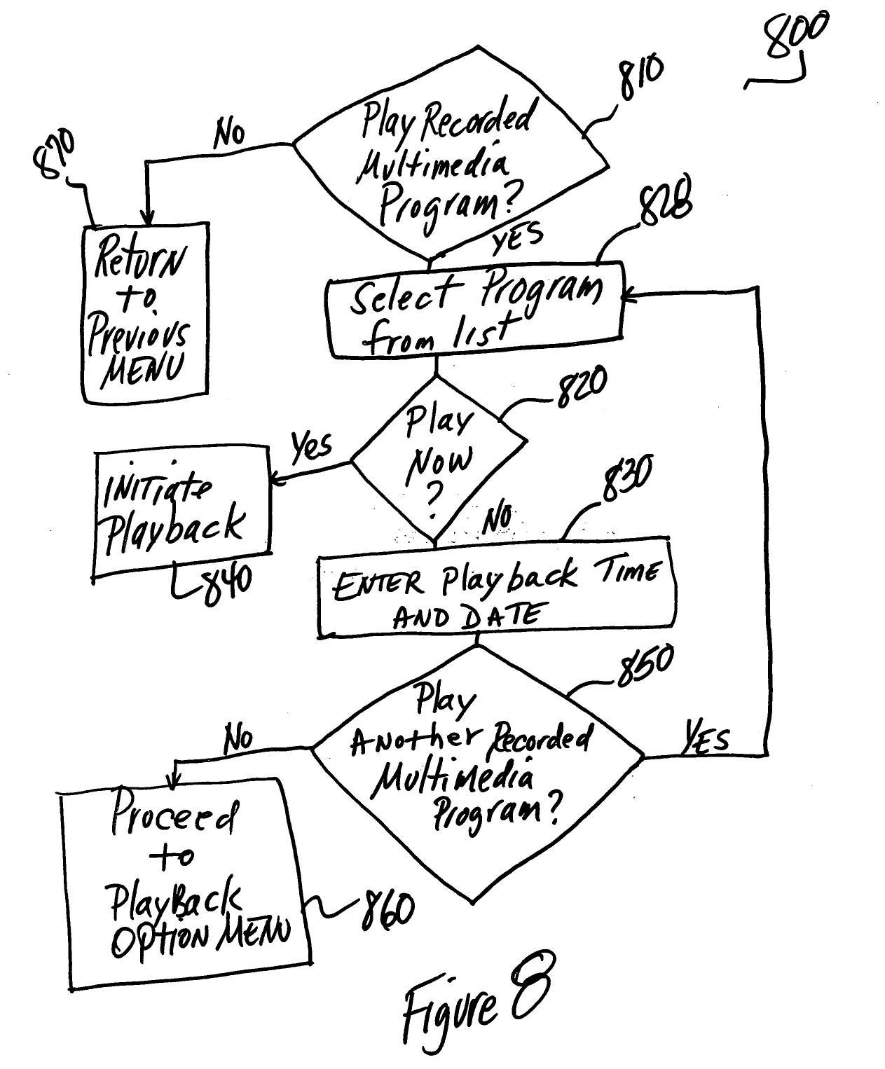

FIG. 8 is a flow diagram 800 illustrating a method of personal multimedia-program recording applications using an electronic device according to an embodiment of the present invention. In an embodiment according to the present invention, the end-user may desire to watch one or both recorded programs, continuing the example above, consecutively, two days later at 7:00 PM, for example.

The electronic device may be adapted to prompt the end-user to play recorded multimedia-programs 810. If the end-user answers negatively, the electronic device may return to a previous menu 870 or to an options menu. If the end-user responds affirmatively, however, the electronic device may be adapted to enable an end-user to toggle through a list of stored and/or recorded multimedia-programs and select playback of a desired multimedia-program(s) 828. When a multimedia-program has been selected for playback, the electronic device may prompt the end-user to answer whether the end-user desires to play the selected recorded multimedia-program now 820, wherein if the end-user responds affirmatively, the electronic device may immediately initiate playback 840.

If the end-user responds negatively to the play now prompt, i.e., the end-user does not desire to play the selected recorded multimedia-program immediately, the electronic device may be adapted to prompt the end-user to enter a playback time and date 830. According to the continuing example, the end-user may enter 7 PM May 2, 2004 for playback of the first recorded multimedia-program. The end-user may also be prompted to answer whether the end-user desires to play another recorded multimedia-program 850, wherein if the end-user responds negatively, the electronic device may advance to a further options menu 860. In an embodiment according to the present invention, the further options menu may comprise a list of playback options, such as for example, widescreen format, full screen format, language for playback, delete commercials, audio settings, video settings, etc.

If the end-user responds affirmatively, the electronic device may prompt the end-user to select another multimedia-program by again toggling through the list of recorded multimedia-programs 828. According to the continuing example, the end-user may enter 8 PM May 2, 2004 for playback of the second recorded multimedia-program. The end-user may also be prompted to answer whether the end-user desires to play another recorded multimedia-program 850, wherein if the end-user responds negatively, the electronic device may advance to a further options menu 860. If the end-user responds affirmatively, the electronic device may prompt the end-user to select another multimedia-program by again toggling through the list of recorded multimedia-programs 828, repeating the above steps.

In an embodiment according to the present invention, the electronic device, for example, may enter a HIBERNATE state/mode after receiving a plurality of end-user commands, for example, record, playback, settings, etc. The electronic device may remain in the HIBERNATE state/mode until entering another state/mode, such as, for example, the STAND-BY state/mode. Upon entering the STAND-BY state/mode, the electronic device may initiate recording of the first multimedia-program, for example, at 10:00 AM the next day and may remain in the STAND-BY state/mode until 11:00 AM, wherein recording of the first multimedia-program may be completed. The electronic device may once again enter into the HIBERNATE state/mode until an additional multimedia-program event is imminent.

The above-recited sequence may be repeated for the second multimedia-program recording. At some later time, for example, two days later at 7:00 PM, the electronic device may leave the HIBERNATE state/mode and enter a POWER-ON state/mode, wherein the display device may power on and initiate playback of the recorded multimedia-programs.

In an embodiment according to the present invention, the end-user may instantly play at least one of the recorded multimedia-programs anytime the end-user desires by pressing a specified key(s) on the remote control.

Aspects of the present invention may be found in a sequence of power-saving states/modes being automatically controlled by an electronic device. In an embodiment according to the present invention, an end-user may be prompted to provide an electronic device with a plurality of program commands associated with a plurality of multimedia-programs and the electronic device may be adapted to process the commands, determine power-saving states/modes to efficiently perform the commands, employ the determined power-saving states/modes, and perform the commands.

Aspects of the present invention may be found in an automatic switch-on (power on) feature in an electronic device. In an embodiment according to the present invention, the electronic device may be provided with a real-time clock built into the electronic device. The real-time clock may also support and be associated with the power-saving states/modes active in the electronic device. The real-time clock may be set manually by an end-user or automatically via a time control signal associated with received communication from the electronic device network or service provider of multimedia-program.

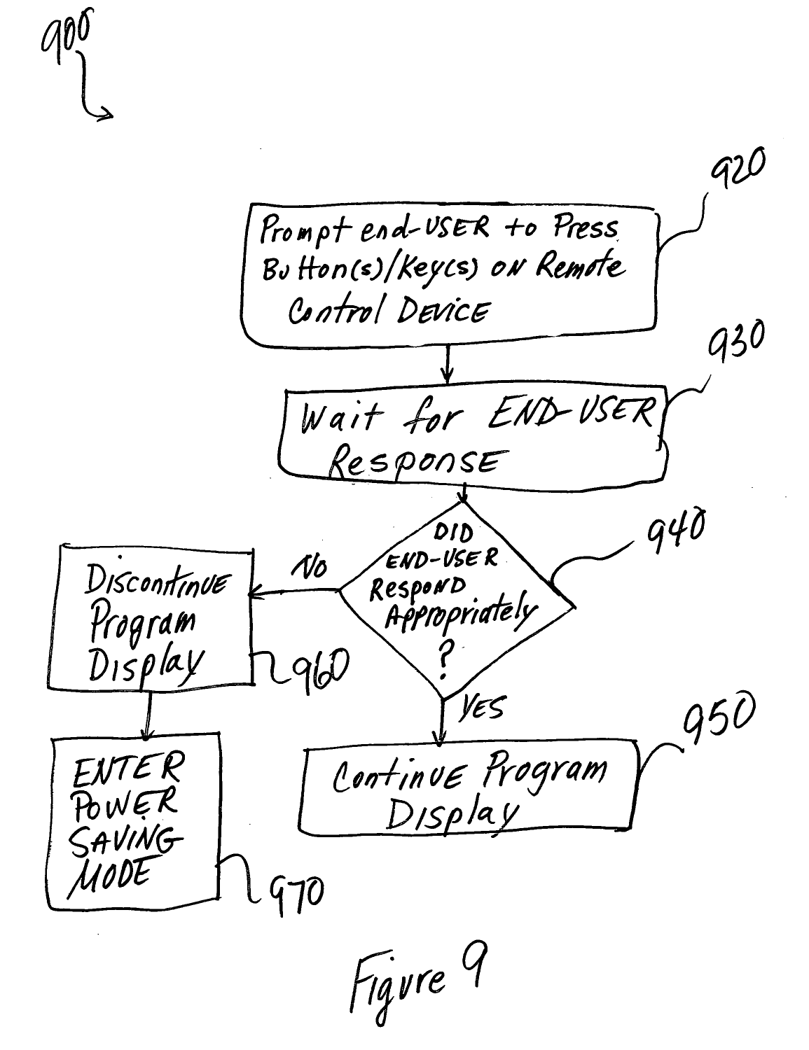

FIG. 9 is a flow diagram 900 illustrating a method of determining by an electronic device if an end-user is in the physical presence of the electronic device. Aspects of the present invention may also be found in determining whether the end-user is physically present when the program display command is initiated.

In an embodiment according to the present invention, the end-user may be prompted to press a button(s)/key(s), a sequence of buttons/keys, a pre-set password, or a value displayed on the display device/entity (screen), generated randomly by the electronic device 920, on a remote control device indicating that the end-user is physically present and confirming that the recorded multimedia-program is to be displayed on the electronic device. The electronic device may be adapted to wait a specific period of time to permit the end-user to locate the remote control device and respond 930.

The electronic device, after waiting a specific amount of time, determines whether the end-user responded appropriately to the prompt 940. If the end-user is not physically present, and/or an incorrect response to the electronic device prompt is received, the electronic device may be adapted to discontinue program display 960 and/or prevent program display. The electronic device may enter a power-saving state/mode 970, such as, for example, the HIBERNATE state/mode, the STAND-BY state/mode, or the POWER-OFF state/mode, after a brief period of time has elapsed.

If the end-user responds to the prompt by pressing an appropriate button(s)/key(s) on the remote control device, a sequence of buttons/keys, a pre-set password, or a value displayed on the screen (generated randomly by the electronic device), the electronic device may be adapted to continue or initiate multimedia-program display 950.

Aspects of the present invention may be found in a digital circuit board integrated into an electronic device for performing the power-saving states/modes and power-saving methods. In an embodiment according to the present invention, the power-saving states/modes and methods may be adapted to be provided as firmware/software stored on an integrated circuit or a programmable logic device or chip.

In an embodiment according to the present invention, the integrated circuit, Application Specific Integrated Circuit (ASIC), programmable logic device, or chip may be adapted to be installed and operate in an STB, a digital TV product, or any other electronic device, such as those set forth above.

Aspects of the present invention may be found in power-saving states/modes, such as, for example, the Advanced Power Management (APM) standard, the Advanced Configuration and Power Interface (ACPI) standard, the Display Power Management System (DPMS) standard, etc. The DPMS standard, for example, is a system that reduces the amount of energy consumed by a display device, (e.g., a monitor); when the display device is idle.

Aspects of the present invention may be found in power-saving states/modes implemented in STBs. In an embodiment according to the present invention, STBs may be mobile wireless enabled STBs. Accordingly, power considerations may be important, for example, conserving and managing power. A power supply may comprise a battery or a plurality of batteries. The batteries may be standard batteries, for example, alkaline, etc., or the batteries may be rechargeable-type batteries. The batteries may be rechargeable within the electronic device or alternatively may be replaceable and/or rechargeable after being removed from the electronic device.

In an embodiment according to the present invention, the electronic device may be provided with a power control processor/controller adapted to regulate the power usage, reduce the power consumption, and increase the battery life by evaluating the power usage and ensuring that power is not being wasted, for example, when the electronic devices are idle or when an end-user is not present to receive the multimedia-program being displayed.

Aspects of the present invention may be found in a plurality of power-saving states/modes employable by electronic devices adapted to regulate the power usage, reduce the power consumption, and the increase battery life.

In another embodiment according to the present invention, all circuitry of the electronic device may be switched off or powered off. In an embodiment according to the present invention, the end-user's settings and/or preferences may be stored in a memory device, such as for example, FLASH memory or an additional secondary storage device, such as, a hard drive, which may not require power consumption to maintain stored information.

Aspects of the present invention may be found in methods of setting the plurality of power-saving states/modes set forth above.

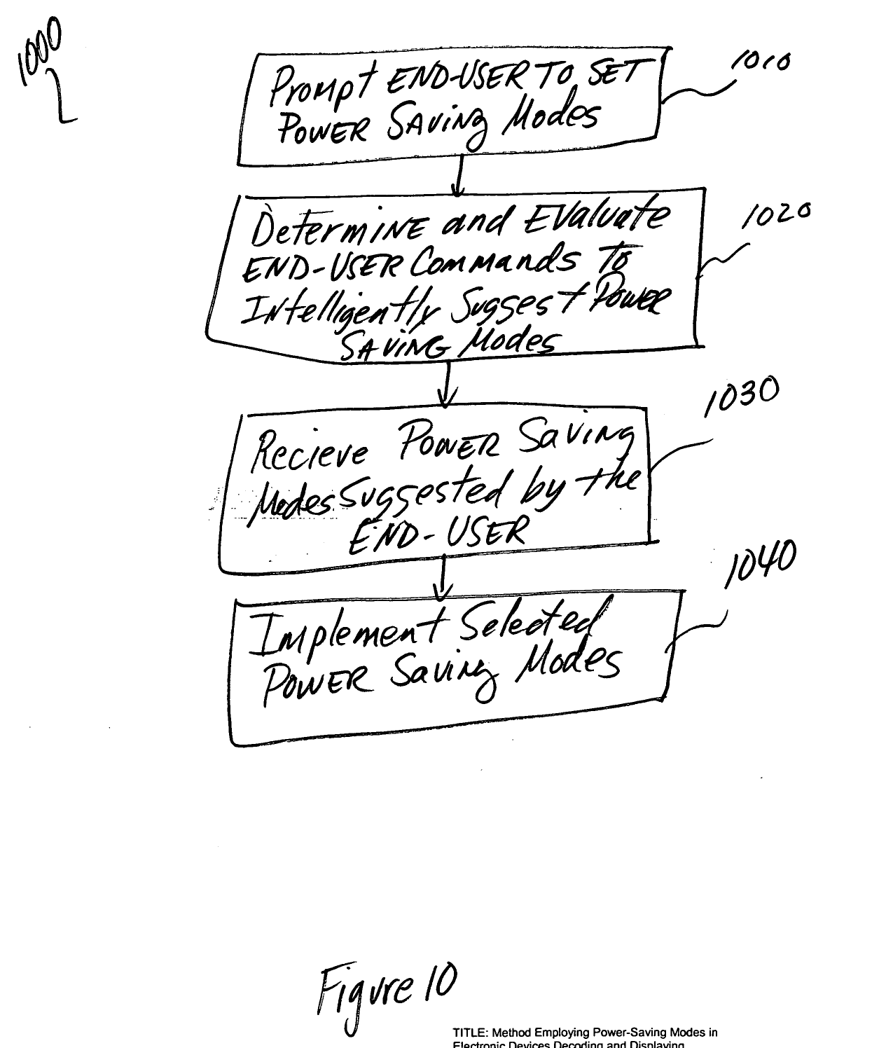

FIG. 10 is a flow diagram 1000 illustrating a method of setting power-saving states/modes in an electronic device according to an embodiment of the present invention. In an embodiment according to the present invention, an end-user may be prompted by the electronic device to set the power-saving states/modes 1010. The electronic device may be provided with an end-user viewable and accessible menu having a plurality of power-saving options for the end-user to select.

The electronic device may be adapted to suggest particular power-saving states/modes for the end-user to select by evaluating and determining the end-user's desired outcome 1020. The electronic device may be adapted to evaluate a plurality of end-user commands, wherein the evaluation may permit the electronic device to suggest and prompt an end-user to select from a plurality of appropriate selections for power-saving states/modes associated with the end-user commands being entered. The electronic device may be adapted to receive the suggested and selected power-saving states/modes chosen by the end-user 1030, wherein the selected power-saving states/modes may be stored in non-volatile memory. In an embodiment according to the present invention, the power-saving states/modes may be implemented autonomously without interaction with the end-user 1040.

In an embodiment according to the present invention, if it is determined that the display device/entity is inactive, (the electronic device may be adapted to sense that the display device/entity is inactive), the electronic device may be adapted to autonomously enter either the STAND-BY state/mode or the HIBERNATE state/mode. The electronic device may be adapted to provide the autonomous power-saving state/mode selection options by prompting an end-user to select the power-saving option, or may be enter the power-saving states/modes as default electronic device power-saving configurations. The electronic device may also prompt the end-user to enable or disable the autonomous electronic device power-saving options by selecting an appropriate setting from an electronic device menu.

In an embodiment according to the present invention, the electronic device may be adapted to determine whether an end-user is receiving/watching/viewing, etc., multimedia-program information being displayed or broadcast. For example, the electronic device may be adapted to prevent unnecessary power consumption when an end-user has fallen asleep or has left the physical area where the electronic device is displaying or broadcasting multimedia-program information.

In an embodiment according to the present invention, the electronic device may be adapted to prompt the end-user to press some button(s)/key(s) on a remote control device at predetermined or random intervals of time, wherein if the end-user fails to appropriately respond to the prompt within a particular period of time, the electronic device may be adapted to turn off at least the display device/entity.

In an embodiment according to the present invention, the electronic device may also be adapted to turn off all electronic circuitry and autonomously enter the POWER-OFF state/mode, for example, or alternatively, to enter the STAND-BY state/mode or the HIBERNATE state/mode. The electronic device may be adapted to prompt an end-user to turn the power-saving options off/on by selecting from a plurality of menu options.

In an embodiment according to the present invention, the electronic device may be adapted to determine whether the display device/entity is receiving input signals from a multimedia-program distribution network, either via a wire/cable or wirelessly. In an embodiment according to the present invention, the electronic device may be adapted to switch off or power off the display device/entity, the decoding device/entity, and circuitry associated respectively therewith and enter one of the power-saving states/modes set forth above.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

1. A multimedia-program distribution network, the network comprising:
a plurality of electronic devices communicatively coupled to the network; and
a power control module, wherein the power control module is adapted to monitor power consumption of at least one of the plurality of electronic devices.

2. The network according to claim 1, wherein the power control module is adapted to determine whether an end-user is present and receiving a multimedia-program from an electronic device.

3. The network according to claim 2, wherein if the power control module determines that an end-user is one of absent from the electronic device, unresponsive to the electronic device, and a display apparatus is inactive, the power control module is adapted to reduce the power consumption of the electronic device by commanding the electronic device to enter at least one of a plurality of power-saving modes.

4. The network according to claim 3, wherein determining whether the display apparatus is one of active and inactive comprises evaluating at least one component of the display apparatus.

5. The network according to claim 3, wherein the at least one of a plurality of power-saving modes comprises at least one of a POWER-ON mode, a STAND-BY mode, a POWER-OFF mode, a HIBERNATE mode, an electronic device determined mode, an end-user determined mode, and a network determined mode.

6. The network according to claim 2, wherein determining whether an end-user is present and receiving the multimedia-program from the electronic device comprises prompting the end-user to respond to a message delivered by the electronic device.

7. The network according to claim 6, wherein the message delivered by the electronic device comprises one of an audio message, a visual message, and a combination audio/video message.

8. The network according to claim 6, wherein responding to the message delivered by the electronic device comprises at least one of:
pressing one of a button and a key on at least one of a remote control device, the electronic device, and a peripheral associated electronic device;
pressing a sequence of one of buttons and keys on at least one of the remote control device, the electronic device, and the peripheral associated electronic device;
entering at least one of a password and username on at least one of the remote control device, the electronic device, and the peripheral associated electronic device;
entering a particular response to an interactive question delivered by the electronic device upon at least one of the remote control device, the electronic device, and the peripheral associated electronic device; and
employing a biometric authentication technique via at least one of the remote control device, the electronic device, and the peripheral associated electronic device.

9. The network according to claim 1, wherein the plurality of electronic devices and the network are adapted to communicate via one of a wire, a cable, an optical fiber, and wirelessly in two-way communication.

10. The network according to claim 1, wherein a multimedia-program comprises one of audio, video, text, documents, Internet communication, and wireless telephony.

11. The network according to claim 1, wherein the plurality of electronic devices comprising:
at least one of an audio decoding entity, a video decoding entity, and a combination audio/video decoding entity;
at least one of an audio broadcast entity, a video display entity, and a combination audio/video display entity; and
at least one of firmware and software adapted to employ a plurality of power-saving modes, wherein the plurality of electronic devices comprise one of a digital multimedia-program recorder, a video cassette player, a video cassette recorder, a digital video disc player, a digital video disc recorder, an MP3 audio player, a mobile cellular phone, a wired telephone, a wireless cellular handset, a personal digital assistant, an audio tape player, an audio tape recorder, a compact disc player, a compact disc recorder, a digital still camera, a digital video camera, and a gaming console.

12. The network according to claim 1, further comprising:
at least one multimedia-program distribution device;
at least one satellite receiving and transmitting distributed multimedia-program information; and
at least one satellite receiver receiving the transmitted distributed multimedia-program information and conveying the distributed multimedia-program information to at least one local service provider location for dissemination to the plurality of electronic devices.

13. The network according to claim 1, further comprising a subscriber database memory, the subscriber database memory being accessed to determine whether a particular end-user is subscribed to and authorized to receive a particular multimedia-program being requested.

14. An electronic device comprising:
at least one decoder for decoding audio and video information;
a transmitter for transmitting multimedia-program requests to a multimedia-program distribution network;
a receiver for receiving multimedia-program information transmitted from the multimedia-program distribution network; and
a power control module for monitoring and evaluating power consumption of the electronic device.

15. The electronic device according to claim 14, wherein the power control module is adapted to implement and employ at least one of a plurality of power-saving modes to reduce power consumption and prevent power waste.

16. The electronic device according to claim 15, wherein the at least one of a plurality of power-saving modes comprises at least one of a POWER-ON mode, a STAND-BY mode, a POWER-OFF mode, a HIBERNATE mode, an electronic device determined mode, an end-user determined mode, and a network determined mode.

17. The electronic device according to claim 14, wherein the power control module is adapted to determine whether an end-user is present and receiving a multimedia-program from the electronic device.

18. The electronic device according to claim 14, wherein the electronic device is adapted to prompt the end-user to respond to a message delivered by the electronic device.

19. The electronic device according to claim 18, wherein the message delivered by the electronic device comprises one of an audio message, a visual message, and a combination audio/video message.

20. The electronic device according to claim 14, wherein responding to the message delivered by the electronic device comprises at least one of:
pressing one of a button and a key on at least one of a remote control device, the electronic device, and a peripheral associated electronic device;
pressing a sequence of one of buttons and keys on at least one of the remote control device, the electronic device, and the peripheral associated electronic device;
entering at least one of a password and username on at least one of the remote control device, the electronic device, and the peripheral associated electronic device;
entering a particular response to an interactive question delivered by the electronic device upon at least one of the remote control device, the electronic device, and the peripheral associated electronic device; and
employing a biometric authentication technique via at least one of the remote control device, the electronic device, and the peripheral associated electronic device.

21. The electronic device according to claim 14, wherein the electronic device is adapted to communicate via one of a wire, a cable, an optical fiber, and wirelessly in two-way communication with the multimedia-program distribution network.

22. The electronic device according to claim 14, wherein a multimedia-program comprises one of audio, video, text, documents, Internet communication, and wireless telephony.

23. The electronic device according to claim 14, wherein the power control module is adapted to determine whether a display apparatus is one of active and inactive.

24. The electronic device according to claim 14, wherein the at least one decoder for decoding audio and video information comprises at least one of an audio decoding entity, a video decoding entity, and a combination audio/video decoding entity.

25. The electronic device according to claim 14, further comprising at least one of an audio broadcast entity, a video display entity, and a combination audio/video display entity.

26. The electronic device according to claim 14, wherein the electronic device comprises one of a digital multimedia-program recorder, a video cassette player, a video cassette recorder, a digital video disc player, a digital video disc recorder, an MP3 audio player, a mobile cellular phone, a wired telephone, a wireless cellular handset, a personal digital assistant, an audio tape player, an audio tape recorder, a compact disc player, a compact disc recorder, a digital still camera, a digital video camera, and a gaming console.

27. The electronic device according to claim 14, wherein the electronic device is adapted to determine whether a particular end-user is subscribed to and authorized to receive a particular multimedia-program being requested before sending a multimedia program request to the multimedia-program distribution network, wherein if the end-user is unsubscribed and unauthorized to receive the particular multimedia-program requested, the electronic device delivers a message to the end-user.

28. The electronic device according to claim 14, wherein the transmitter and the receiver comprise one of a single entity and separate entities.

29. The electronic device according to claim 14, wherein the power control module is adapted to determine whether a display apparatus is one of active and inactive by evaluating at least one component of the display apparatus.

30. A method of controlling power consumption in an electronic device, the method comprising:
monitoring activity of the electronic device; and
entering at least one of a plurality of power-saving modes upon determining that the electronic device is wasting power.

31. The method according to claim 30, wherein determining that the electronic device is wasting power at least comprises one of determining that an end-user is absent from the electronic device and determining that an electronic device's service is unused by an end-user.

32. The method according to claim 31, wherein determining that the electronic device is wasting power comprises determining whether a display apparatus is one of active and inactive.

33. The method according to claim 31, wherein determining that the end-user is absent and the electronic device's service is unused comprises:
prompting the end-user to respond to a message; and
waiting a particular amount of time to receive a response.

34. The method according to claim 33, further comprising entering the at least one power saving mode if no response is received.

35. The method according to claim 33, further comprising:
receiving the response;
evaluating the response; and
authenticating the response, wherein if the response is determined to be authentic, determining that the end-user is present and using the electronic device's service.

36. The method according to claim 35, wherein the response comprises at least one of:
input received from one of a button and a key pressed on at least one of a remote control device, the electronic device, and a peripheral associated electronic device;
input received from a sequence of one of buttons and keys pressed on at least one of the remote control device, the electronic device, and the peripheral associated electronic device;
input received from at least one of a password and username entered on at least one of the remote control device, the electronic device, and the peripheral associated electronic device;
input received from a particular response to an interactive question delivered by the electronic device entered on at least one of the remote control device, the electronic device, and the peripheral associated electronic device; and
input received from a biometric authentication technique via at least one of the remote control device, the electronic device, and the peripheral associated electronic device.

37. The method according to claim 33, further comprising:
receiving the response;
evaluating the response; and
authenticating the response, wherein if the response is determined to be inauthentic, determining that a valid end-user is absent and entering at least one of the plurality of power-saving modes and a security mode.

38. The method according to claim 37, wherein the response comprises at least one of:
input received from one of a button and a key pressed on at least one of a remote control device, the electronic device, and a peripheral associated electronic device;
input received from a sequence of one of buttons and keys pressed on at least one of the remote control device, the electronic device, and the peripheral associated electronic device;
input received from at least one of a password and username entered on at least one of the remote control device, the electronic device, and the peripheral associated electronic device;
input received from a particular response to an interactive question delivered by the electronic device entered on at least one of the remote control device, the electronic device, and the peripheral associated electronic device; and
input received from a biometric authentication technique via at least one of the remote control device, the electronic device, and the peripheral associated electronic device.

39. The method according to claim 30, wherein the at least one of a plurality of power-saving modes comprises at least one of a POWER-ON mode, a STAND-BY mode, a POWER-OFF mode, a HIBERNATE mode, an electronic device determined mode, an end-user determined mode, and a network determined mode.

40. The method according to claim 39, wherein in the POWER-OFF mode, all circuits of the electronic device are one of switched off and inactive.

41. The method according to claim 39, wherein in the STAND-BY mode, a portion of electronic device circuits are one of switched on and active and a portion of electronic device circuits are one of switched off and inactive.

42. The method according to claim 39, wherein in the HIBERNATE mode, electronic device circuits associated with maintaining in a volatile memory one of an end-user's settings and an end-user's preferences remain active and a balance of the electronic device circuits are one of switched off and inactive.

43. The method according to claim 39, wherein in the POWER-ON mode, all circuits of the electronic devices are one of switched on and active.

44. The method according to claim 30, wherein monitoring activity of the electronic device is performed during electronic device start-up, wherein upon determining that a valid end-user is present, the electronic device is adapted to enter the POWER-ON mode.

45. The method according to claim 32, wherein determining whether a display apparatus is one of active and inactive comprises evaluating at least one component of the display apparatus.

46. The method according to claim 30, wherein the electronic device enters the POWER-ON mode upon being switched on, wherein monitoring activity of the electronic device is performed, and the electronic device enters a different power-saving mode depending upon whether an end-user is one of present and absent.

47. The method according to claim 30, wherein the electronic device enters a POWER-ON mode upon being switched on, wherein monitoring activity of the electronic device is performed, and the electronic device enters a different power-saving mode depending upon whether a display apparatus is one of active and inactive.

48. The method according to claim 30, wherein the electronic device enters a power saving mode when an end-user one of:
presses one of a button and a key on at least one of a remote control device, the electronic device, and a peripheral associated electronic device;
presses a sequence of one of buttons and keys on at least one of the remote control device, the electronic device, and the peripheral associated electronic device;
enters at least one of a password and username on at least one of the remote control device, the electronic device, and the peripheral associated electronic device;
enters a particular response to an interactive question delivered by the electronic device upon at least one of the remote control device, the electronic device, and the peripheral associated electronic device; and
employs a biometric authentication technique via at least one of the remote control device, the electronic device, and the peripheral associated electronic device.

49. The method according to claim 30, wherein the electronic device enters a power-saving mode depending upon a state of at least a portion of at least one of hardware, firmware, and software in the electronic device.
